(19) United States
(12) Patent Application Publication
(10) Pub. No.: US 2023/0253345 A1
(43) Pub. Date: Aug. 10, 2023

(54) SEMICONDUCTOR DEVICE, POWER CONVERSION APPARATUS, AND METHOD FOR MANUFACTURING SEMICONDUCTOR DEVICE

(71) Applicant: Mitsubishi Electric Corporation, Tokyo (JP)

(72) Inventors: Kohei EBIHARA, Tokyo (JP); Fumihito MASUOKA, Tokyo (JP); Masanori TSUKUDA, Tokyo (JP); Akihiko FURUKAWA, Tokyo (JP)

(73) Assignee: Mitsubishi Electric Corporation, Tokyo (JP)

(21) Appl. No.: 18/057,735

(22) Filed: Nov. 21, 2022

(30) Foreign Application Priority Data
Feb. 7, 2022 (JP) 2022-017244

(51) Int. Cl. H01L 23/00; H01L 23/31; H01L 29/16

(52) U.S. Cl. CPC H01L 23/564; H01L 23/3171; H01L 23/3192; H01L 29/1608

(57) ABSTRACT

A semiconductor device includes a field insulating film formed on an epitaxial layer, a front surface electrode covering an inner peripheral end of the field insulating film, and an outer peripheral electrode covering an outer peripheral end of the field insulating film. In a surface layer portion of the epitaxial layer, a termination well region that is connected to the front surface electrode and extends to the outside of an outer peripheral end of the front surface electrode is formed. The semi-insulating film is formed so as to cover a part of the field insulating film apart from the front surface electrode and the outer peripheral electrode. The semi-insulating film is connected to the epitaxial layer through an opening formed in the field insulating film in each of a region inside and a region outside an outer peripheral end of the termination well region.

### FIELD OF THE INVENTION

The present disclosure relates to a semiconductor device, and particularly to a semiconductor device having a surface protective film.

### DESCRIPTION OF THE BACKGROUND ART

In a vertical semiconductor device used for a power device or the like, a technique of providing a p-type guard ring region (termination well region) in what is called a termination region of an outer peripheral portion of an n-type semiconductor layer in order to ensure withstand voltage performance is known. In a semiconductor device having a guard ring region, an electric field generated when reverse voltage is applied to a main electrode of the semiconductor device is relaxed by a depletion layer formed by a pn junction between an n-type semiconductor layer and a p-type guard ring region.

For example, Japanese Patent Application Laid-Open No. 6-275852 (1994) discloses a semiconductor device having a structure including a semi-insulating film provided on an outer end portion of a p-type guard ring with an insulating film interposed between them, and a front surface electrode connected to each of an inner end portion and an outer end portion of the semi-insulating film. With this structure, a potential gradient in a termination region of the semiconductor device is kept constant, and an electric field is more effectively relaxed.

Further, a front surface electrode of the semiconductor device may be covered with polyimide as a surface protective film or sealed using a sealing material such as gel, except for a region where wire bonding is performed.

A surface protective film such as polyimide and a sealing material such as gel tend to contain moisture under high humidity. This moisture may adversely affect a front surface electrode. Specifically, the front surface electrode may be dissolved in moisture, or the front surface electrode may react with moisture to deposit an insulating material. In such a case, peeling is likely to occur at an interface between the front surface electrode and the surface protective film or the sealing gel. A cavity on an outer periphery of the front surface electrode generated by peeling of the surface protective film or the sealing gel may act as a leak path and impair insulation reliability of a semiconductor device. Further, regardless of the presence or absence of the surface protective film, in a case where an insulating material is deposited on the front surface electrode, stress is applied to a material other than the front surface electrode, and there is a possibility that insulation reliability of the semiconductor device is impaired.

### SUMMARY

An object of the present disclosure is to provide a semiconductor device having high insulation reliability.

A semiconductor device according to the present disclosure includes a semiconductor layer of a first conductivity type, and a field insulating film formed on a surface of the semiconductor layer.

A front surface electrode, which is an inner peripheral electrode covering an inner peripheral end of the field insulating film, is formed on a surface of the semiconductor layer inside the field insulating film.

An outer peripheral electrode covering an outer peripheral end of the field insulating film is formed on a surface of the semiconductor layer outside the field insulating film.

In a surface layer portion of the semiconductor layer, a well region of a second conductivity type connected to the front surface electrode and extending to the outside of an outer peripheral end of the front surface electrode is formed.

A semi-insulating film is formed so as to cover a part of the field insulating film while being separated from the front surface electrode and the outer peripheral electrode.

A back surface electrode is formed on a back surface side of the semiconductor layer.

The semi-insulating film is connected to the semiconductor layer through an opening formed in the field insulating film in each of a region inside and a region outside an outer peripheral end of the well region.

According to the semiconductor device of the present disclosure, it is possible to prevent an insulating material from being deposited on the front surface electrode.

This can contribute to improvement in insulation reliability of the semiconductor device.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a partial cross-sectional view illustrating a configuration of a semiconductor device according to a first preferred embodiment;

FIG. 2 is a plan view illustrating a configuration of the semiconductor device according to the first preferred embodiment;

FIG. 3 is a partial cross-sectional view illustrating a configuration of the semiconductor device according to a first variation of the first preferred embodiment;

FIG. 4 is a partial cross-sectional view illustrating a configuration of the semiconductor device according to a second variation of the first preferred embodiment;

FIGS. 5 to 8 are partial cross-sectional views each illustrating a configuration of the semiconductor device according to a third variation of the first preferred embodiment;

FIG. 9 is a partial cross-sectional view illustrating a configuration of the semiconductor device according to a second preferred embodiment;

FIG. 10 is a plan view illustrating a configuration of the semiconductor device according to the second preferred embodiment;

FIG. 11 is a partial cross-sectional view illustrating a configuration of a unit cell of the semiconductor device according to the second preferred embodiment;

FIG. 12 is a plan view illustrating a configuration of the semiconductor device according to a first variation of the second preferred embodiment;

FIG. 13 is a partial cross-sectional view illustrating a configuration of the semiconductor device according to a second variation of the second preferred embodiment;

FIG. 14 is a plan view illustrating a configuration of the semiconductor device according to the second variation of the second preferred embodiment;

FIG. 15 is a partial cross-sectional view illustrating a configuration of the semiconductor device according to a third variation of the second preferred embodiment;

FIG. 16 is a plan view illustrating a configuration of the semiconductor device according to the third variation of the second preferred embodiment;

FIGS. 17 to 22 are partial cross-sectional views each illustrating a configuration of the semiconductor device according to a fourth variation of the second preferred embodiment;

FIGS. 23 and 24 are partial plan views each illustrating a configuration of the semiconductor device according to the fourth variation of the second preferred embodiment; and

FIG. 25 is a block diagram illustrating a configuration of a power conversion system to which a power conversion apparatus according to a third preferred embodiment is applied.

### DESCRIPTION OF THE PREFERRED EMBODIMENTS

Hereinafter, a preferred embodiment of a technique according to the present disclosure will be described. In the present description, an “active region” of a semiconductor device is defined as a region through which main current flows when the semiconductor device is in an ON state, and a “termination region” of the semiconductor device is defined as a region around the active region. Further, “outside” or “outer side” of the semiconductor device means a direction from a central portion toward an outer peripheral portion of the semiconductor device, and “inside” or “inner side” of the semiconductor device means a direction opposite to “outside” or “inner side”. Further, a conductivity type of an impurity will be described assuming that a “first conductivity type” is an n-type and a “second conductivity type” is a p-type, but conversely, the “first conductivity type” may be a p-type and the “second conductivity type” may be an n-type.

Here, the term “MOS” was used to represent a laminated structure of metal-oxide-semiconductor in the past, and is an acronym for Metal-Oxide-Semiconductor. However, particularly in a field effect transistor (hereinafter, simply referred to as a “MOS transistor”) having a MOS structure, materials of a gate insulating film and a gate electrode have been improved from the viewpoint of recent integration, improvement of a manufacturing process, and the like. For example, in a MOS transistor, polycrystalline silicon is becoming employed instead of metal as a material of a gate electrode mainly from the viewpoint of forming a source and a drain in a self-aligned manner. Further, from the viewpoint of improving electrical characteristics, a material having a high dielectric constant is used for a gate insulating film, but the material is not necessarily limited to an oxide.

Therefore, the term “MOS” is not necessarily limited to a laminated structure of metal-oxide-semiconductor, and the same applies to the present description. That is, in view of the common general technical knowledge, “MOS” is defined not only as an abbreviation of Metal-Oxide-Semiconductor but also as broadly including a laminated structure of conductor-insulator-semiconductor.

Further, in description below, even if “on” and “cover” are described, the presence of an inclusion between constituent elements is not excluded. For example, even if it is described as “B provided on A” or “B covering A”, other constituent elements may be provided between A and B. Further, in description below, terms that mean specific positions or directions such as “upper”, “lower”, “side”, “bottom”, “front”, or “back” may be used, but these terms are used for convenience of description and are not related to directions in actual use.

Diagrams illustrated below are schematic. For this reason, sizes, positions, and mutual relationships of elements illustrated in the diagrams are not limited to accurate ones, and can be appropriately changed. Further, a mutual relationship between sizes and positions of elements illustrated in different diagrams is not limited to one that is accurate, and may be appropriately changed.

In each of the diagrams, constituent elements having names and functions similar to those illustrated in another diagram are denoted by the same reference numerals. For this reason, description of elements similar to those described previously with reference to another diagram may be omitted in order to avoid redundant description.

### First Preferred Embodiment

[Device Configuration]

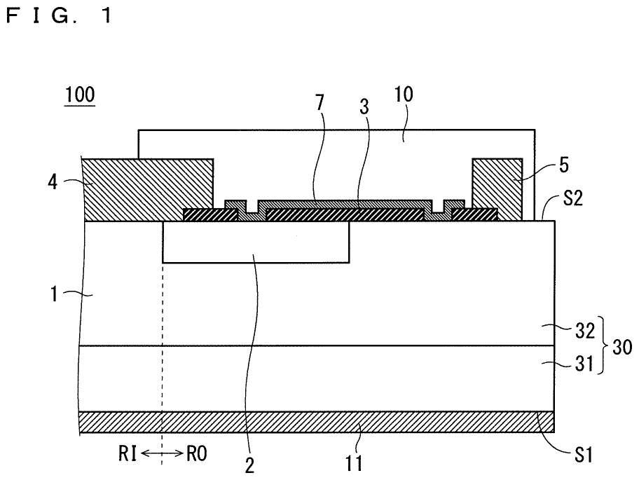

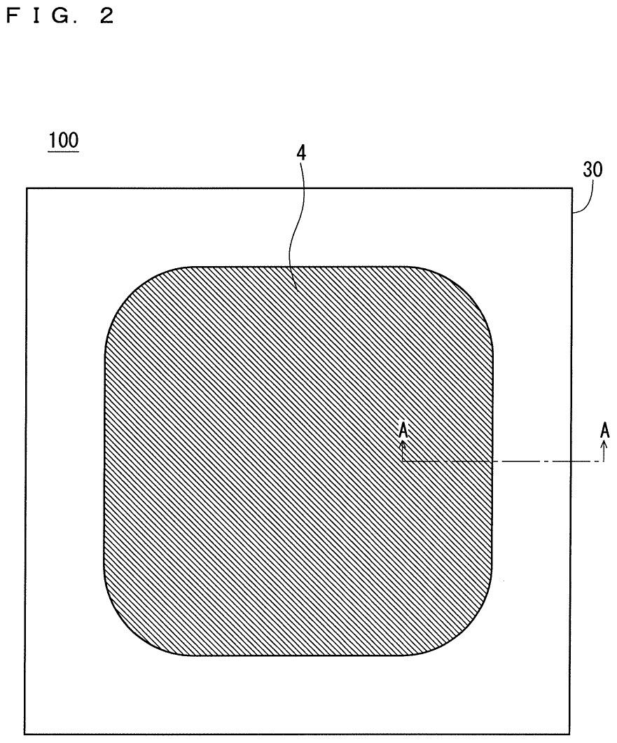

FIG. 1 is a partial cross-sectional view of a Schottky barrier diode (SBD) 100 which is a semiconductor device according to a first preferred embodiment. FIG. 2 is a plan view of the SBD 100, and a cross-sectional view taken along line A-A of FIG. 2 and as viewed from an arrow corresponds to FIG. 1. A left side portion of FIG. 1 is an active region through which main current flows in an ON state of the SBD 100, and a right side portion of FIG. 1 is a termination region which is a region outside the active region of the SBD 100. Hereinafter, a region corresponding to the active region is referred to as “inner region RI”, and a region corresponding to the termination region is referred to as “outer region RO”.

As illustrated in FIG. 1, the SBD 100 is formed using an epitaxial substrate 30 including a single crystal substrate 31 and an epitaxial layer 32 formed on the single crystal substrate 31. The single crystal substrate 31 is a semiconductor substrate made from n-type (first conductivity type) silicon carbide (SiC), and the epitaxial layer 32 is a semiconductor layer made from SiC epitaxially grown on the single crystal substrate 31. That is, the SBD 100 is a SiC-SBD. In the present preferred embodiment, the epitaxial substrate 30 having a polytype of 4H is used.

Here, the upper side of the epitaxial substrate 30 in FIG. 1 is defined as “front side”, and the lower side is defined as “back side”. Hereinafter, a main surface on the back side of the epitaxial substrate 30 is referred to as “back surface S1”, and a main surface on the front side is referred to as “front surface S2”. Further, since the back surface S1 of the epitaxial substrate 30 is also a main surface of the single crystal substrate 31, the back surface S1 may also be referred to as “back surface S1 of the single crystal substrate 31”. Similarly, since the front surface S2 of the epitaxial substrate 30 is also a main surface of the epitaxial layer 32, the front surface S2 may also be referred to as “front surface S2 of the epitaxial layer 32”.

A p-type (second conductivity type) termination well region 2 is selectively formed in a surface layer portion on the front side of the epitaxial layer 32 in the termination region. The termination well region 2 is a frame-like (ring-like) region surrounding the active region in plan view, and functions as what is called a guard ring. Further, as illustrated in FIG. 1, an end portion on the inner side of the termination well region 2 (also referred to as “inner peripheral end”) is defined as a boundary between the inner region RI which is the active region and the outer region RO which is the termination region.

An n-type region excluding the termination well region 2 of the epitaxial layer 32 is a drift layer 1 through which current flows due to drift. An impurity concentration of the drift layer 1 is lower than an impurity concentration of the single crystal substrate 31. For this reason, the single crystal substrate 31 has a resistivity lower than that of the drift layer 1. Here, an impurity concentration of the drift layer 1 is set to 1×10¹⁴/cm³ or more and 1×10¹⁷/cm³ or less.

The termination well region 2 may include a plurality of regions having different impurity concentrations. Further, the number of the terminal well regions 2 is not limited to one, and for example, a plurality of the terminal well regions 2 arranged in a nested manner spaced apart from each other may be provided in the outer region RO. That is, the termination well region 2 may be divided into a plurality of regions.

A field insulating film 3, a front surface electrode 4, an outer peripheral electrode 5, a semi-insulating film 7, and a surface protective film 10 are provided on the front surface S2 of the epitaxial substrate 30. Further, a back surface electrode 11 is provided on the back surface S1 of the epitaxial substrate 30. Note that, in the plan view of FIG. 2, only the epitaxial substrate 30 and the front surface electrode 4 are illustrated, and illustration of other elements is omitted.

The field insulating film 3 covers a part of the termination well region 2 and extends to the outside of the termination well region 2 beyond an end portion on the outer side (also referred to as an “outer peripheral end”) of the termination well region 2. Further, a plurality of opening portions through which the front surface S2 of the epitaxial substrate 30 is exposed are formed in the field insulating film 3. Specifically, in the field insulating film 3, an opening portion exposing the front surface S2 of the active region of the epitaxial substrate 30 across the inner region RI and the outer region RO, an opening portion exposing the front surface S2 of the termination well region 2 of the outer region RO, and an opening portion exposing the front surface S2 of a region outside the termination well region 2 are formed.

The front surface electrode 4 is formed across the inner region RI and the outer region RO, and is connected to at least a part of the front surface S2 of the epitaxial substrate 30 through an opening portion of the field insulating film 3. In the present preferred embodiment, the front surface electrode 4 is provided over the entire inner region RI, and is connected to the termination well region 2 in the outer region RO. The termination well region 2 is connected to an outer peripheral portion of the front surface electrode 4 and extends to the outside of an outer peripheral end of the front surface electrode 4. Further, the outer peripheral end of the front surface electrode 4 covers an inner peripheral end of the field insulating film 3.

A material of the front surface electrode 4 may be any metal as long as the metal forms a Schottky junction with the drift layer 1 which is an n-type SiC semiconductor, and for example, titanium (Ti), molybdenum (Mo), nickel (Ni), gold (Au), tungsten (W), or the like can be used. Further, the front surface electrode 4 may have a laminated structure in which any metal of Al (aluminum), Cu (copper), Mo, and Ni, or an Al alloy such as Al—Si is laminated on any of the above materials.

The outer peripheral electrode 5 is provided outside the termination well region 2 to be separated from the termination well region 2, and is connected to at least a part of the front surface S2 of the outer region RO of the epitaxial substrate 30. In the present preferred embodiment, an inner peripheral end of the outer peripheral electrode 5 covers an outer peripheral end of the field insulating film 3.

As a material of the outer peripheral electrode 5, any metal of titanium (Ti), molybdenum (Mo), nickel (Ni), gold (Au), tungsten (W), aluminum (Al), and copper (Cu), or an Al alloy such as Al—Si can be used. Further, the outer peripheral electrode 5 may have a laminated structure including two or more of these materials.

The semi-insulating film 7 is provided on at least a part of the field insulating film 3 in the outer region RO. The semi-insulating film 7 is separated from the front surface electrode 4 and the outer peripheral electrode 5 so as not to be in contact with the front surface electrode 4 and the outer peripheral electrode 5. Further, the semi-insulating film 7 is connected to the front surface S2 of the epitaxial layer 32 through an opening portion formed in the field insulating film 3 in each of a region inside and a region outside an outer peripheral end of the termination well region 2. Specifically, the semi-insulating film 7 is connected to the front surface S2 of the termination well region 2 and the front surface S2 of the termination well region 2 through an opening portion formed in the field insulating film 3.

As a material of the semi-insulating film 7, SInSiN (Semi-Insulated SiN), SIPOS (Semi-Insulated Polycrystalline Silicon), or the like can be used. In the present preferred embodiment, SInSiN is used as a material of the semi-insulating film 7, and a resistivity of the semi-insulating film 7 is less than 1×10¹² Ω·cm. In the semi-insulating film 7, a lower layer portion in contact with the front surface S2 of the epitaxial substrate 30 preferably has semi-insulating properties. Therefore, the semi-insulating film 7 may have a laminated structure in which, for example, a SiN film having high moisture resistance is laminated on an anti-insulating material.

The surface protective film 10 is formed on the semi-insulating film 7 and covers an outer peripheral end of the front surface electrode 4 and the outer peripheral electrode 5. A material of the surface protective film 10 is preferably an insulating resin material capable of relaxing stress, such as polyimide or polybenzoxazole. Note that, in a case where the SBD 100 is used by being covered with sealing gel having a low elastic modulus such as silicone gel, the surface protective film 10 may be omitted.

In the inner region RI, the surface protective film 10 is provided with an opening for exposing a region where wire bonding or the like of the front surface electrode 4 is performed. Further, in the outer region RO, the surface protective film 10 is provided with an opening portion exposing a region where dicing or the like of the epitaxial substrate 30 is performed.

FIG. 1 illustrates one cross section (cross section taken along line A-A in FIG. 2) of a terminal portion of the SBD 100 according to the first preferred embodiment. However, a region where the semi-insulating film 7 is in contact with the front surface S2 of the epitaxial substrate 30 via an opening portion of the field insulating film 3 does not need to be formed over the entire circumference surrounding the front surface electrode 4 in plan view, and may be divided into a plurality of regions separated from each other.

In the present preferred embodiment, a material of the epitaxial substrate 30 is SiC. A SiC semiconductor has a wide band gap wider than that of a Si semiconductor, and a SiC semiconductor device is excellent in withstand voltage, has a higher allowable current density, and has higher heat resistance than a Si semiconductor device, so that the SiC semiconductor device can operate at a high temperature. However, the material of the epitaxial substrate 30 is not limited to SiC, and may be Si or another wide band gap semiconductor such as gallium nitride (GaN).

Further, the semiconductor device according to the present preferred embodiment may be a diode other than an SBD, for example, a pn junction diode or a junction barrier Schottky (JBS) diode.

[First Variation]

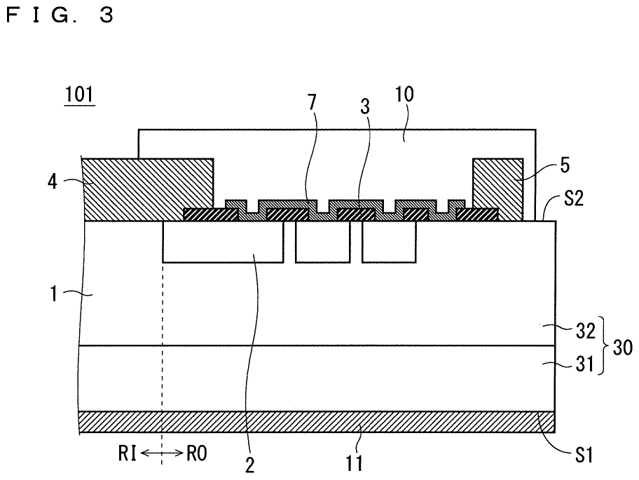

FIG. 3 is a cross-sectional view illustrating a configuration of an SBD 101 which is the semiconductor device according to a first variation of the first preferred embodiment. In the SBD 101 of FIG. 3, the termination well region 2 is divided into a plurality of regions. The field insulating film 3 has an opening portion on each of a plurality of the termination well regions 2. The semi-insulating film 7 is connected to each of the divided termination well regions 2 via an opening portion formed in the field insulating film 3, and is connected to the front surface S2 of the epitaxial substrate 30 in a region outside an outermost one of the termination well regions 2.

[Second Variation]

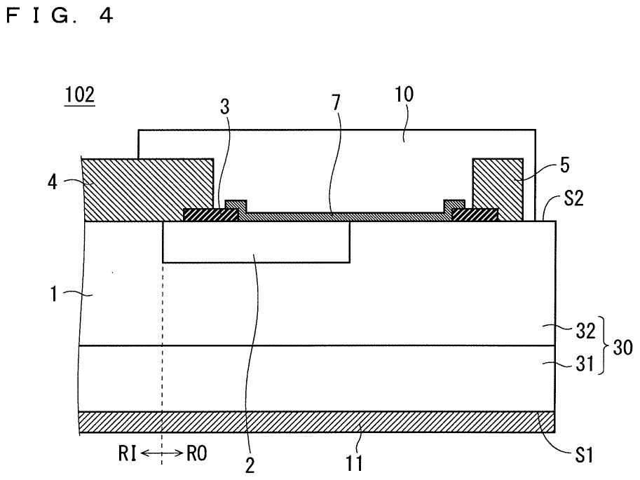

FIG. 4 is a cross-sectional view illustrating a configuration of an SBD 102 which is the semiconductor device according to a second variation of the first preferred embodiment. In the SBD 102 of FIG. 4, the field insulating film 3 has an opening portion extending over the inside and the outside of an outer peripheral end of the termination well region 2. The semi-insulating film 7 is connected to the front surface S2 of the epitaxial substrate 30 in the termination well region 2 and a region outside the termination well region 2 via an opening portion formed in the field insulating film 3.

[Third Variation]

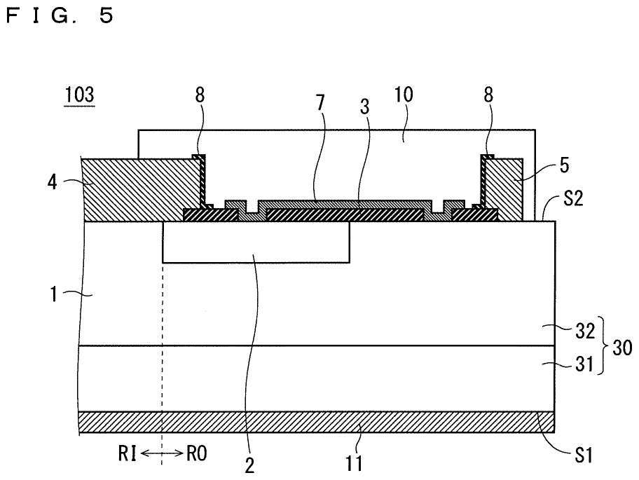

FIG. 5 is a cross-sectional view illustrating a configuration of an SBD 103 which is the semiconductor device according to the second variation of the first preferred embodiment. In the SBD 103 of FIG. 5, a moisture-resistant insulating film 8 is formed so as to cover an outer peripheral end of the front surface electrode 4 and an inner peripheral end of the outer peripheral electrode 5. Further, in the inner region RI, the moisture-resistant insulating film 8 is provided with an opening that exposes a region where wire bonding or the like of the front surface electrode 4 is performed.

As a material of the moisture-resistant insulating film 8, an insulating film having high moisture resistance such as SiN, SiON, or SiOC is used. In the present preferred embodiment, SiN is used as a material of the moisture-resistant insulating film 8, and a resistivity of the moisture-resistant insulating film 8 is 1×10¹² Ω·cm or more. A film thickness of SiN is 100 nm or more and 2000 nm or less, preferably 300 nm or more and 1500 nm or less, more preferably 500 nm or more and 1000 nm or less, and can be, for example, 500 nm.

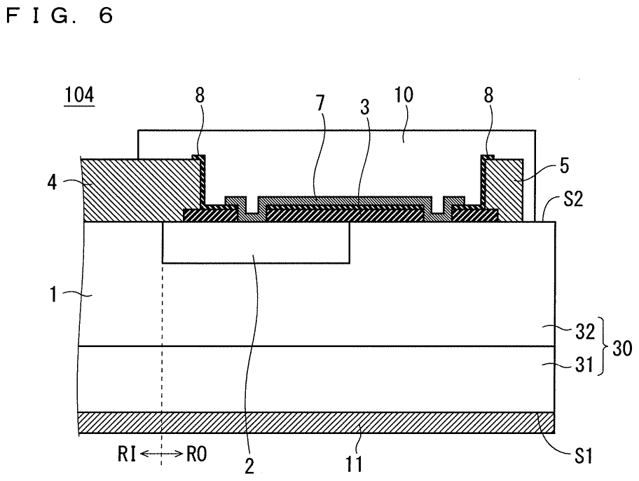

As illustrated in FIG. 6, the moisture-resistant insulating film 8 may have an opening portion at the same position as an opening portion of the field insulating film 3 on the termination well region 2 and in a region outside the termination well region 2. That is, an opening portion provided on the termination well region 2 and an opening portion provided in a region outside the termination well region 2 may be formed so as to penetrate the moisture-resistant insulating film 8 and the field insulating film 3.

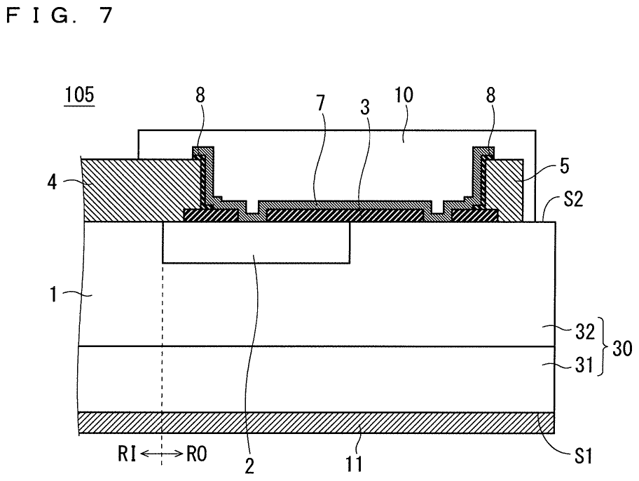

As illustrated in FIG. 7, the semi-insulating film 7 may be formed so as to cover the moisture-resistant insulating film 8 and have an opening portion at the same position as an opening portion of the moisture-resistant insulating film 8 on the front surface electrode 4 and the outer peripheral electrode 5. Also in this case, the semi-insulating film 7 is formed so as not to be connected to the front surface electrode 4 and the outer peripheral electrode 5.

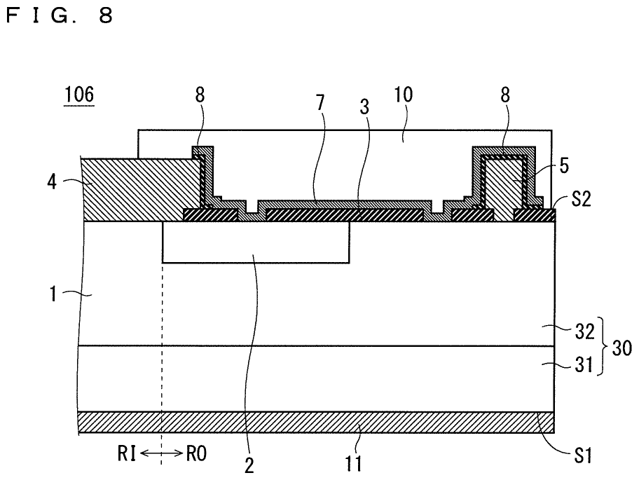

As illustrated in FIG. 8, the moisture-resistant insulating film 8 may completely cover the outer peripheral electrode 5. In this case, the semi-insulating film 7 and the moisture-resistant insulating film 8 are provided with an opening that exposes a region where dicing or the like of the epitaxial substrate 30 is performed. The field insulating film 3 may be formed so as to extend from below an outer peripheral end of the outer peripheral electrode 5 to a region where dicing or the like of the epitaxial substrate 30 is performed.

[Operation]

Next, operation of the SBD 100 of the first preferred embodiment described with reference to FIG. 1 will be described. When negative voltage based on potential of the front surface electrode 4 is applied to the back surface electrode 11, the SBD 100 is in a state in which current flows from the front surface electrode 4 toward the back surface electrode 11, that is, a conduction state (ON state). On the other hand, when positive voltage based on potential of the front surface electrode 4 is applied to the back surface electrode 11, the SBD 100 is in a blocked state (OFF state).

When the SBD 100 is in the OFF state, a large electric field is applied to a surface of the active region of the drift layer 1 and the vicinity of a pn junction interface between the drift layer 1 and the termination well region 2. Voltage to the back surface electrode 11 when this electric field reaches a critical electric field and avalanche breakdown occurs is defined as maximum voltage (avalanche voltage). Normally, rated voltage is determined such that the SBD 100 is used in a voltage range in which avalanche breakdown does not occur.

In the OFF state, a depletion layer expands in a direction from a surface of the active region of the drift layer 1 and a pn junction interface between the drift layer 1 and the termination well region 2 toward the single crystal substrate 31 (downward direction) and in an outer peripheral direction of the drift layer 1 (rightward direction). Further, a depletion layer also expands from a pn junction interface between the drift layer 1 and the termination well region 2 into the termination well region 2, and degree of the expansion greatly depends on a concentration of the termination well region 2. That is, when a concentration of the termination well region 2 increases, the expansion of the depletion layer is suppressed in the termination well region 2, and a tip position of the depletion layer inside the termination well region 2 becomes a position close to a boundary between the termination well region 2 and the drift layer 1.

Here, a case where the SBD 100 is set to the OFF state under high humidity is considered. In a case where the surface protective film 10 is made from polyimide or the like, the surface protective film 10 contains a large amount of moisture under high humidity. When the moisture reaches surfaces of the front surface electrode 4 and the outer peripheral electrode 5, the front surface electrode 4 functions as a cathode and the outer peripheral electrode 5 functions as an anode by voltage applied to the SBD 100 in the OFF state. Even in a case where the surface protective film 10 is not formed, a large amount of moisture permeates sealing gel and reaches the SBD 100, and similarly, the front surface electrode 4 functions as a cathode and the outer peripheral electrode 5 functions as an anode.

In the vicinity of the front surface electrode 4 serving as a cathode, a reduction reaction of oxygen represented by Formula (1) below and a formation reaction of hydrogen represented by Formula (2) occur with respect to the moisture.

O₂+2H₂O+4e⁻→4OH⁻ (1)

H₂O+e⁻→OH⁻+1/2H₂ (2)

Along with this, a concentration of hydroxide ions increases in the vicinity of the front surface electrode 4. Hydroxide ions chemically react with the front surface electrode 4. For example, in a case where the front surface electrode 4 is made from aluminum, aluminum may become aluminum hydroxide by the chemical reaction. Further, aluminum hydroxide may become aluminum oxide depending on ambient temperature, pH, and the like.

Further, in the vicinity of the outer peripheral electrode 5 serving as an anode, for example, in a case where the outer peripheral electrode 5 is made from aluminum, aluminum dissolves as Al₃⁺ and reacts with surrounding moisture to become aluminum hydroxide or aluminum oxide.

These aluminum hydroxides or aluminum oxides are deposited as an insulating material on surfaces of the front surface electrode 4 and the outer peripheral electrode 5. By this deposition, a film on the front surface electrode 4 and the outer peripheral electrode 5 is broken or pushed up and peeled off, and when peeling progresses to form a cavity portion in an upper portion of the field insulating film 3, moisture enters the cavity portion. The moisture that enters the cavity portion may cause excessive leakage current, aerial discharge in the cavity portion, and the like, and may cause element destruction of the SBD. Further, in a case where volume expansion occurs due to deposition of the insulating material, stress is applied to the field insulating film 3 and the epitaxial substrate 30 under the front surface electrode 4 and the outer peripheral electrode 5, which may cause physical breakdown of the SBD 100 and cause element destruction.

The deposition reaction of aluminum hydroxide or aluminum oxide is accelerated by electric field strength. In particular, an outer peripheral end portion of the front surface electrode 4 and an inner peripheral end portion of the outer peripheral electrode 5 are likely to have a high electric field, and in a case where the epitaxial substrate 30 is made from silicon carbide, a higher electric field strength is generated in the outer region RO, and a deposition reaction of aluminum hydroxide or aluminum oxide is accelerated.

In the semiconductor device of Japanese Patent Application Laid-Open No. 6-275852 (1994) described above, the semi-insulating film 7 is connected to an outer peripheral end of the front surface electrode 4 and an inner peripheral end of the outer peripheral electrode 5, and moisture of the surface protective film 10 reaches an end portion of the front surface electrode 4 and the outer peripheral electrode 5 through the semi-insulating film 7, and electrons are exchanged between the front surface electrode 4 and the outer peripheral electrode 5 through the semi-insulating film 7, so that a deposition reaction of aluminum hydroxide or aluminum oxide is further accelerated. Furthermore, due to conductivity of the semi-insulating film 7, a potential gradient is likely to occur around an outer peripheral end portion of the front surface electrode 4 and an inner peripheral end portion of the outer peripheral electrode 5, and there is also a possibility that a precipitation reaction of aluminum hydroxide or aluminum oxide due to electric field strength is accelerated.

On the other hand, in the SBD 100 of the first preferred embodiment, the semi-insulating film 7 is separated from the front surface electrode 4 and the outer peripheral electrode 5 so as not to be in contact with the front surface electrode 4 and the outer peripheral electrode 5. In this manner, electrons are not directly exchanged between the semi-insulating film 7 and the front surface electrode 4 and between the semi-insulating film 7 and the outer peripheral electrode 5, and a potential gradient does not occur around an outer peripheral end portion of the front surface electrode 4 and an inner peripheral end portion of the outer peripheral electrode 5 due to conductivity of the semi-insulating film 7. As a result, deposition of aluminum hydroxide or aluminum oxide on surfaces of the front surface electrode 4 and the outer peripheral electrode 5 can be suppressed.

Further, in the SBD 100 of the first preferred embodiment, the semi-insulating film 7 is connected to the front surface S2 of the epitaxial substrate 30 through an opening portion formed in the field insulating film 3 in each of the termination well region 2 and a region outside the termination well region 2. For this reason, in the OFF state, a gentle potential gradient is formed in a region where the semi-insulating film 7 is formed. Therefore, it is possible to suppress occurrence of excessive electric field concentration around the termination well region 2.

The above effect can also be obtained in the SBDs 101 to 104 described in the first to third variations of the first preferred embodiment.

In the SBD 101 illustrated in FIG. 3, since the semi-insulating film 7 is connected to a plurality of the termination well regions 2 formed apart from each other through an opening portion of the field insulating film 3, potential of a plurality of the termination well regions 2 is fixed, and electric field concentration around the termination well region 2 can be relaxed more effectively.

In the SBD 102 illustrated in FIG. 4, the semi-insulating film 7 is connected to the front surface S2 of the epitaxial substrate 30 over the termination well region 2 and a region outside the termination well region 2 through an opening portion formed in the field insulating film 3. In this manner, a fixed charge generated when a portion around the termination well region 2 becomes a high electric field is discharged through the semi-insulating film 7, so that reliability of the semiconductor device when high voltage is applied can be enhanced.

In the SBD 103 illustrated in FIG. 5, the moisture-resistant insulating film 8 is formed so as to cover an outer peripheral end of the front surface electrode 4 and an inner peripheral end of the outer peripheral electrode 5. For this reason, moisture is prevented from reaching an outer peripheral end of the front surface electrode 4 and an inner peripheral end of the outer peripheral electrode 5. As a result, a deposition reaction of aluminum hydroxide or aluminum oxide at an outer peripheral end of the front surface electrode 4 and an inner peripheral end of the outer peripheral electrode 5 can be further suppressed.

In an SBD 104 illustrated in FIG. 6, the moisture-resistant insulating film 8 has an opening portion at the same position as an opening portion of the field insulating film 3 on the termination well region 2 of the outer region RO and in a region outside the termination well region 2. For this reason, an opening portion of the field insulating film 3 of the outer region RO can be formed at the same time as when an opening portion of the moisture-resistant insulating film 8 is formed. As a result, damage to the front surface S2 of the epitaxial substrate 30 due to a plurality of times of over-etching can be avoided, and reliability of the semiconductor device when high voltage is applied can be enhanced.

In an SBD 105 illustrated in FIG. 7, the semi-insulating film 7 covers the moisture-resistant insulating film 8, and has an opening portion in the same region as an opening portion of the moisture-resistant insulating film 8 on the front surface electrode 4 and the outer peripheral electrode 5. Also in this case, since the semi-insulating film 7 is separated from the front surface electrode 4 and the outer peripheral electrode 5 without being in contact with the front surface electrode 4 and the outer peripheral electrode 5, deposition of aluminum hydroxide or aluminum oxide on a surface of the front surface electrode 4 and the outer peripheral electrode 5 can be suppressed. Further, since an opening portion of the moisture-resistant insulating film 8 provided on the front surface electrode 4 and the outer peripheral electrode 5 can be formed at the same time as when an opening portion of the semi-insulating film 7 is formed, it is possible to avoid damage onto a surface of the front surface electrode 4 and the outer peripheral electrode 5 due to a plurality of times of over-etching and to enhance reliability of the semiconductor device when high voltage is applied.

In an SBD 106 illustrated in FIG. 8, the moisture-resistant insulating film 8 is formed so as to completely cover the outer peripheral electrode 5. For this reason, moisture is prevented from reaching a surface of the outer peripheral electrode 5. As a result, a deposition reaction of aluminum hydroxide or aluminum oxide on a surface of the outer peripheral electrode 5 can be further suppressed.

[Manufacturing Method]

Hereinafter, a method for manufacturing the SBD 100 according to the first preferred embodiment will be described.

First, the single crystal substrate 31 of low resistance containing n-type impurities at a relatively high concentration (n⁺) is prepared. Here, the single crystal substrate 31 is assumed to be a SiC substrate having a polytype of 4H and has an off angle of four degrees or eight degrees.

Next, SiC is epitaxially grown on the single crystal substrate 31 to form the epitaxial layer 32 of n type having an impurity concentration of 1×10¹⁴/cm³ or more and 1×10¹⁷/cm³ or less. As a result, the epitaxial substrate 30 including the single crystal substrate 31 and the epitaxial layer 32 is obtained.

Next, a resist mask having a predetermined pattern is formed on the epitaxial layer 32 by a photolithography process, and a p-type impurity (acceptor) such as Al or boron (B) is ion-implanted using the resist mask as an implantation mask, so that the p-type termination well region 2 is formed in an upper layer portion of the epitaxial layer 32. A dose amount of the termination well region 2 is preferably 0.5×10¹³/cm² or more and 5×10¹³/cm² or less, and is, for example, 1.0×10¹³/cm².

In a case of Al, implantation energy of ion implantation for forming the termination well region 2 is, for example, 100 keV or more and 700 keV or less. In this case, an impurity concentration converted from the dose amount [cm 2] is 1×10¹⁷/cm³ or more and 1×10¹⁹/cm³ or less.

When the termination well region 2 is formed, a resist mask is patterned so that a plurality of loop-shaped p-type impurity regions are formed in a nested manner, so that the termination well region 2 divided into a plurality of regions as in the SBD 101 of FIG. 3 can be formed. Further, as processes of patterning a resist mask and ion implantation are repeated, it is possible to form the termination well region 2 including a plurality of regions having different impurity concentrations.

After the formation of the termination well region 2, annealing is performed at a temperature of 1300° C. or more and 1900° C. or less for 30 seconds or more and one hour or less in an inert gas atmosphere such as argon (Ar) gas using a heat treatment apparatus. By this annealing, impurities added by ion implantation are activated.

Next, a SiO₂ film having thickness of 1 μm to be the field insulating film 3 is deposited on the front surface S2 of the epitaxial substrate 30 by, for example, a CVD method. After the above a resist mask having a predetermined pattern is formed on the SiO₂ film by a photolithography process, and the SiO₂ film is etched using the resist mask as an etching mask to form the field insulating film 3. In this etching, the SiO₂ film in a region where the front surface electrode 4 and the outer peripheral electrode 5 are brought into contact with the front surface S2 of the epitaxial substrate 30 and a region where the semi-insulating film 7 is brought into contact with the front surface S2 of the epitaxial substrate 30 are removed. That is, the SiO₂ film is removed in a formation region of the front surface electrode 4, a formation region of the outer peripheral electrode 5, the termination well region 2, and a region outside the termination well region 2. Here, in a case where the SBD 104 of FIG. 6 is formed, the SiO₂ film on the termination well region 2 and a region outside the termination well region 2 is not removed in this process.

Next, for example, a Ti film having thickness of 100 nm and an Al film having thickness of 3 μm are formed in this order on the epitaxial layer 32 by, for example, a sputtering method. After the above, a resist mask having a predetermined pattern is formed on the Al film by a photolithography process, and reactive ion etching (RIE) of the Al film is performed using the resist mask as an etching mask to form the front surface electrode 4 and the outer peripheral electrode 5.

Next, in a case where the SBD 103, the SBD 104, the SBD 105, or the SBD 106 illustrated in FIGS. 5 to 8 is formed, a SiN film to be the moisture-resistant insulating film 8 is formed. At this time, a flow rate ratio between silane gas (SiH₄) as a raw material of the SiN film and ammonia gas (NH₃) or nitrogen gas (N₂), film formation temperature, power density, and the like are adjusted, so that a resistivity of the SiN film is set to 1×10¹² Ω·cm or more. A resistivity of the SiN film is correlated with a refractive index, and a refractive index is approximately 2.2 or less. After the above, a resist mask having a predetermined pattern is formed on the SiN film by a photolithography process, and the SiN film is etched using the resist mask as an etching mask to form the moisture-resistant insulating film 8. Here, in a case where the SBD 104 of FIG. 6 is formed, in this process, an opening portion of the moisture-resistant insulating film 8 and an opening portion of the field insulating film 3 may be simultaneously formed in the termination well region 2 and in a region outside the termination well region 2 (specifically, a region that connects the semi-insulating film 7 and the front surface S2 of the epitaxial substrate 30). That is, an opening that penetrates the moisture-resistant insulating film 8 and the field insulating film 3 and exposes a part of the epitaxial layer 32 may be formed. Further, in a case where the SBD 105 or the SBD 106 illustrated in FIG. 7 or FIG. 8 is formed, a SiN film other than that in the region where the semi-insulating film 7 and the front surface S2 of the epitaxial substrate 30 are connected is not removed in this process.

A SiN film to be the moisture-resistant insulating film 8 can also be formed by thermal CVD, and in this case, the composition is stoichiometrically closer to Si₃N₄. A refractive index of Si₃N₄ is about 2.0 or more and 2.1 or less. For this reason, a SiN film formed by thermal CVD becomes a film having more excellent moisture resistance and insulating properties, but film formation temperature is much higher than that of plasma CVD. For this reason, in a case where a material containing Al is used for a material of the front surface electrode 4 or the like, film formation temperature exceeds a melting point of Al, and the SiN film cannot be formed by thermal CVD. In a case where a material of the front surface electrode 4 or the like is, for example, Cu or the like and does not contain Al, the SiN film can be formed by thermal CVD.

Next, a SInSiN film to be the semi-insulating film 7 is formed by, for example, plasma CVD. At this time, a flow rate of silane gas (SiH₄) or the like as a raw material is adjusted, so that a resistivity of the SInSiN film is set to be less than 1×10¹² Ω·cm. A resistivity of the SInSiN film is correlated with a refractive index, and a refractive index generally exceeds 2.2, but the refractive index may be 2.2 or less as a bonding state in the film is changed depending on a manufacturing method or the like. After the above, a resist mask having a predetermined pattern is formed on the SInSiN film by a photolithography process, and the SInSiN film is etched using the resist mask as an etching mask to form the semi-insulating film 7. Here, in a case where the SBD 105 and the SBD 106 in FIGS. 7 and 8 are formed, in this process, an opening portion of the semi-insulating film 7 and an opening portion of the moisture-resistant insulating film 8 provided in a region other than a region where the semi-insulating film 7 and the front surface S2 of the epitaxial substrate 30 are connected may be formed simultaneously. That is, an opening portion that penetrates the semi-insulating film 7 and the moisture-resistant insulating film 8 and exposes a part of the front surface electrode 4 and a part of the outer peripheral electrode 5 or the field insulating film 3 may be formed.

When a material of the semi-insulating film 7 is formed, the semi-insulating film 7 may have a laminated structure as a SiN film having high moisture resistance and high insulation is formed on the SInSiN film.

Note that, in the example illustrated in FIG. 8, the field insulating film 3 is also provided in a region outside the outer peripheral electrode 5 so that damage to the epitaxial substrate 30 when the SiN film and the SInSiN film are etched is suppressed.

Next, for example, photosensitive polyimide is applied, and the surface protective film 10 having a predetermined pattern is formed by a photolithography process. Note that, in a case where the SBD 100 is used by being covered with sealing gel having a low elastic modulus such as silicone gel, formation of the surface protective film 10 may be omitted.

After the above, the back surface electrode 11 is formed on the back surface S1 of the epitaxial substrate 30 by, for example, a sputtering method, so that the configuration of the SBD 100 illustrated in FIG. 1 is obtained.

Note that the back surface electrode 11 may be formed before or after a process of forming the front surface electrode 4 and the outer peripheral electrode 5. As a material of the back surface electrode 11, metal or the like containing one or a plurality of Ti, Ni, Al, Cu, and Au can be used. Thickness of the back surface electrode 11 is preferably 50 nm or more and 2 μm or less, and for example, the back surface electrode 11 may be formed of a two-layer film (Ti/Au) of Ti and Au each having thickness of 1 μm or less.

[Conclusion]

According to the first preferred embodiment and the variation of the first preferred embodiment, deposition of an insulating material on a surface of the front surface electrode 4 and the outer peripheral electrode 5 is suppressed. Further, a potential gradient of a termination region becomes gentle, excessive electric field concentration is suppressed, and insulation reliability of the SBD can be enhanced.

### Second Preferred Embodiment

[Device Configuration]

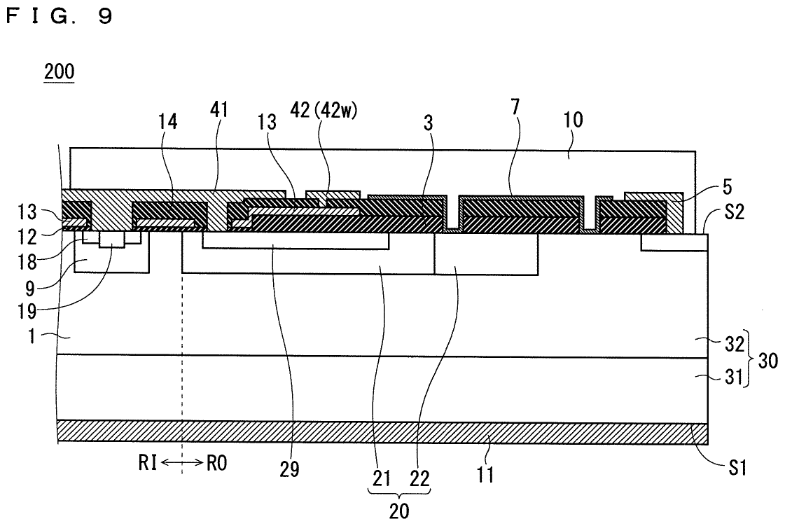

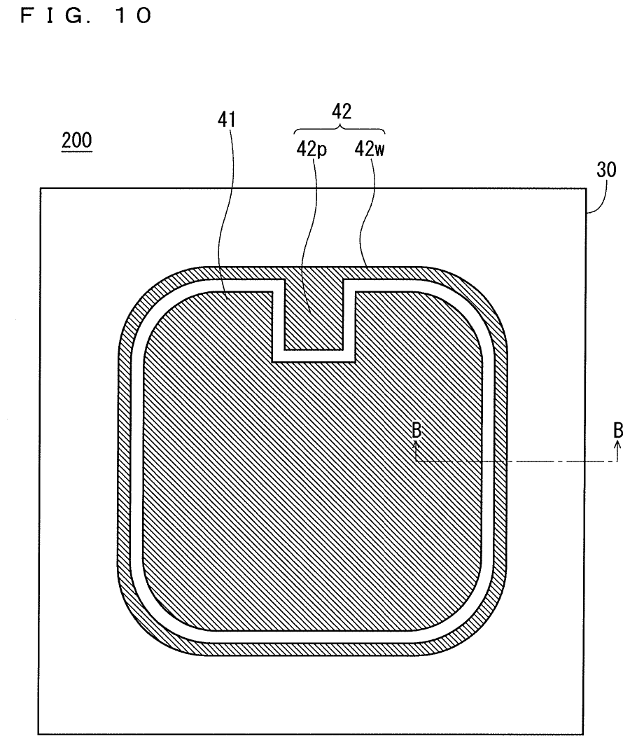

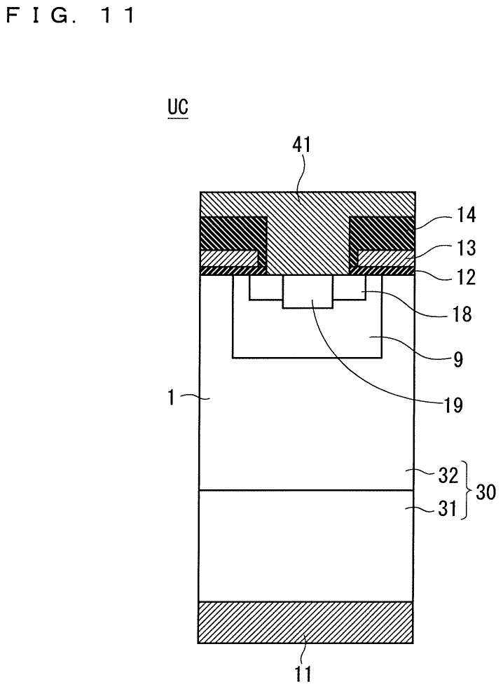

FIG. 9 is a partial cross-sectional view illustrating a configuration of a MOSFET 200 which is a semiconductor device according to a second preferred embodiment. FIG. 10 is a plan view of the MOSFET 200, and a cross-sectional view taken along line B-B in FIG. 10 as viewed from an arrow corresponds to FIG. 9. Further, FIG. 11 is a cross-sectional view illustrating a configuration of a unit cell UC which is a minimum unit structure of a MOSFET formed in the inner region RI which is the active region. A plurality of the unit cells UC illustrated in FIG. 11 are arranged in the inner region RI of the MOSFET 200 (an outermost peripheral one of the unit cells UC is illustrated in a left end portion of FIG. 9). Note that, in FIGS. 9 to 11, elements having the same functions as those of the constituent elements of the SBD 100 according to the first preferred embodiment illustrated in FIGS. 1 and 2 are denoted by the same reference numerals, and thus description overlapping with that of the first preferred embodiment is omitted here.

As illustrated in FIG. 9, the MOSFET 200 is formed using an epitaxial substrate including the single crystal substrate 31 and the epitaxial layer 32 formed on the single crystal substrate 31. The single crystal substrate 31 is a semiconductor substrate made from n-type (first conductivity type) silicon carbide (SiC), and the epitaxial layer 32 is a semiconductor layer made from SiC epitaxially grown on the single crystal substrate 31. That is, the MOSFET 200 is a SiC-MOSFET. In the present preferred embodiment, the epitaxial substrate 30 having a polytype of 4H is used.

A p-type (second conductivity type) element well region 9 is selectively formed in a surface layer portion on the front side of the epitaxial layer 32 in the active region. Further, an n-type source region 18 and a p-type contact region 19 having a higher impurity peak concentration than that of the element well region 9 are selectively formed in a surface layer portion of the element well region 9.

In a surface layer portion on the front side of the epitaxial layer 32 in the termination region, a p-type termination well region 20 is selectively formed so as to surround the active region. The termination well region 20 includes a high concentration region 21 in contact with a boundary between the inner region RI and the outer region RO, and a low concentration region 22 extending outward from the high concentration region 21 so as to surround the high concentration region 21 and having a lower peak concentration of impurities than the high concentration region 21. Furthermore, a termination contact region 29 having a higher impurity peak concentration than the high concentration region 21 is provided in a surface layer portion of the high concentration region 21. A conductivity type of the termination contact region 29 may be n-type.

An n-type region of the epitaxial layer 32 excluding the above impurity regions (the element well region 9, the source region 18, the contact region 19, and the termination well region 20) is the drift layer 1 through which current flows due to drift. An impurity concentration of the drift layer 1 is lower than an impurity concentration of the single crystal substrate 31. For this reason, the single crystal substrate 31 has a resistivity lower than that of the drift layer 1. Here, an impurity concentration of the drift layer 1 is set to 1×10¹⁴/cm³ or more and 1×10¹⁷/cm³ or less.

The termination well region 20 is a frame-like (ring-like) region surrounding the active region in plan view, and functions as what is called a guard ring. Further, as shown in FIG. 9, with an end portion on the inner side (inner peripheral side) of the termination well region 20 as a boundary, the inner side of the end portion is defined as the inner region RI which is the active region, and the outer side is defined as the outer region RO which is the termination region.

On the front surface S2 of the epitaxial substrate 30 in the active region, a gate insulating film 12 is formed so as to extend over the source region 18, the element well region 9, and the drift layer 1, and a gate electrode 13 is formed on the gate insulating film 12. A surface layer portion of the element well region 9 covered with the gate insulating film 12 and the gate electrode 13, that is, a portion between the source region 18 and the drift layer 1 in the element well region 9 is a channel region where an inversion channel is formed when the MOSFET 200 is turned on.

In the active region, the gate electrode 13 is covered with an interlayer insulating film 14, and a source electrode 41 as a front surface electrode is formed on the interlayer insulating film 14. Therefore, the source electrode 41 and the gate electrode 13 are electrically insulated by the interlayer insulating film 14. As illustrated in FIG. 10, the source electrode 41 is provided over the entire inner region RI.

The source electrode 41 is connected to the source region 18 and the contact region 19 through a contact hole formed in the interlayer insulating film 14. The source electrode 41 and the contact region 19 form an ohmic contact. Further, the back surface electrode 11 functioning as a drain electrode is formed on the back surface S1 of the epitaxial substrate 30.

As illustrated in FIG. 9, a part of the gate insulating film 12, the gate electrode 13, the interlayer insulating film 14, and the source electrode 41 extends to the outer region RO beyond the boundary between the inner region RI and the outer region RO. The source electrode 41 extended to the outer region RO is connected to the termination contact region 29 in the termination well region 20 so as to form an ohmic contact or a Schottky contact through the contact hole formed in the interlayer insulating film 14. Further, the gate electrode 13 extended to the outer region RO is arranged on the high concentration region 21 of the termination well region 20 via the field insulating film 3, and extends in a frame shape in plan view similarly to the high concentration region 21.

A gate wiring electrode 42 formed on the interlayer insulating film 14 is connected to the gate electrode 13 extended to the outer region RO through an opening provided in the interlayer insulating film 14. The gate wiring electrode 42 is a control wiring electrode for receiving a gate signal (control signal) for controlling an electrical path between the source electrode 41 and the back surface electrode 11 as a drain electrode, is provided separately from the source electrode 41, and is electrically insulated from the source electrode 41.

As illustrated in FIG. 10, the gate wiring electrode 42 includes a gate wiring 42w provided so as to surround the source electrode 41, and a gate pad 42p on which wire bonding is performed. In the present preferred embodiment, the source electrode 41 is rectangular in planar view, and the gate pad 42p is provided so as to enter a recess formed on one side of the rectangular source electrode 41. The gate wiring electrode 42 illustrated in FIG. 9 corresponds to the gate wiring 42w. Note that, in the plan view of FIG. 10, only the epitaxial substrate 30, the source electrode 41, and the gate wiring electrode 42 are illustrated, and illustration of other elements is omitted.

In FIG. 10, the gate wiring 42w and the gate pad 42p are directly connected, but the gate wiring 42w and the gate pad 42p may be separated from each other and electrically connected through the gate electrode 13 under the interlayer insulating film 14.

The field insulating film 3 is provided on the front surface S2 of the outer region RO of the epitaxial substrate 30, covers a part of the high concentration region 21 and the entire low concentration region 22, and extends to the vicinity of an end edge portion of the epitaxial substrate 30. The field insulating film 3 is not provided in the inner region RI. That is, the field insulating film 3 is provided with an opening that includes the inner region RI.

In FIG. 9, outer peripheral ends of the gate electrode 13 and the interlayer insulating film 14 cover an inner peripheral end of the field insulating film 3, but the outer peripheral ends of the gate electrode 13 and the interlayer insulating film 14 may not cover the inner peripheral end of the field insulating film 3, and the inner peripheral end of the field insulating film 3 may be connected to a side surface of the outer peripheral end of the interlayer insulating film 14. Further, the field insulating film 3 and the interlayer insulating film 14 may be an integrated film formed at the same time.

The outer peripheral electrode 5 is separated from the termination well region and provided on the front surface S2 of the epitaxial substrate 30. An inner peripheral end of the outer peripheral electrode 5 covers an outer peripheral end of at least one of the field insulating film 3 and the interlayer insulating film 14. In FIG. 9, an inner peripheral end of the outer peripheral electrode 5 covers outer peripheral ends of both the field insulating film 3 and the interlayer insulating film 14.

The semi-insulating film 7 is provided on at least a part of the field insulating film 3 and the interlayer insulating film 14 in the outer region RO. The semi-insulating film 7 is separated from the gate wiring electrode 42 and the outer peripheral electrode 5 so as not to be in contact with the source electrode 41, the gate wiring electrode 42, and the outer peripheral electrode 5. Further, the semi-insulating film 7 is connected to the front surface S2 of the epitaxial substrate 30 through an opening portion formed in the field insulating film 3 and the interlayer insulating film 14 on each of the termination well region 20 and a region outside the termination well region 20.

In FIG. 9, the semi-insulating film 7 is connected to the front surface S2 of the low concentration region 22 of the termination well region 20 through an opening portion formed in the field insulating film 3 and the interlayer insulating film 14, but may be connected to the front surface S2 of the high concentration region 21 or the termination contact region 29.

The surface protective film 10 is provided so as to cover an outer peripheral end of the source electrode 41, an inner peripheral end and an outer peripheral end of the gate wiring electrode 42, and the outer peripheral electrode 5. In the surface protective film 10, an opening is formed on the source electrode 41 and the gate pad 42p. Note that, in a case where the MOSFET 200 is used by being covered with sealing gel having a low elastic modulus such as silicone gel, the surface protective film 10 may be omitted.

FIG. 9 illustrates one cross section (cross section taken along line B-B in FIG. 10) of a terminal portion of the MOSFET 200 according to the second preferred embodiment. However, a region where the semi-insulating film 7 is in contact with the front surface S2 of the epitaxial substrate 30 through an opening portion of the field insulating film 3 and the interlayer insulating film 14 does not need to be formed over the entire circumference surrounding the source electrode 41 and the gate wiring electrode 42 in plan view, and may be divided into a plurality of regions separated from each other.

Note that, in the present preferred embodiment, the epitaxial substrate 30 is assumed to be made from SiC. SiC has a wide band gap wider than that of Si, and a SiC semiconductor device using SiC is excellent in withstand voltage, has a higher allowable current density, and has higher heat resistance than a Si semiconductor device using Si, so that the SiC semiconductor device can operate at high temperature. However, a material of the epitaxial substrate 30 is not limited to SiC, and may be another wide bandgap semiconductor, for example, gallium nitride (GaN). Further, for example, silicon (Si) may be used instead of the wide band gap semiconductor. Further, the semiconductor device may be a transistor other than a MOSFET, and may be, for example, a Junction FET (JFET) or an Insulated Gate Bipolar Transistor (IGBT).

[First Variation]

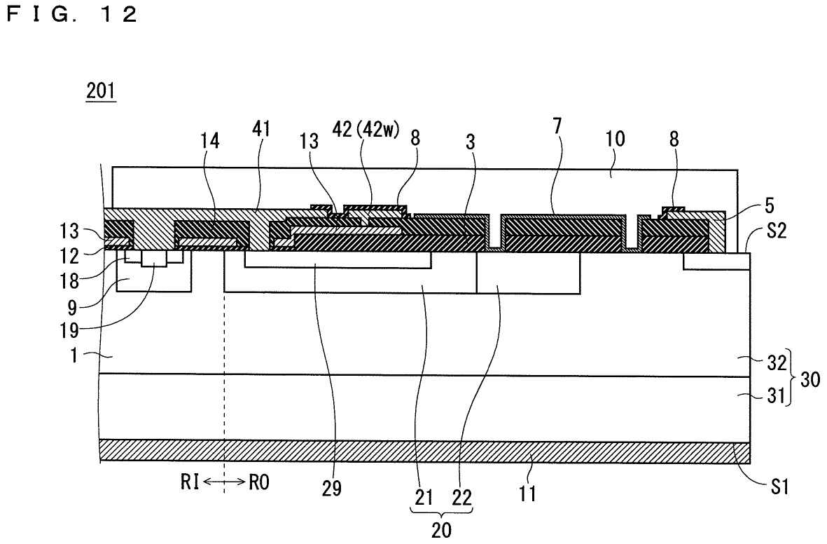

FIG. 12 is a partial cross-sectional view illustrating a configuration of a MOSFET 201 which is a semiconductor device according to a first variation of the second preferred embodiment. In the MOSFET 201 of FIG. 12, the moisture-resistant insulating film 8 is formed so as to cover an outer peripheral end of the source electrode 41, the gate wiring 42w, and an inner peripheral end of the outer peripheral electrode 5.

In the inner region RI, the moisture-resistant insulating film 8 is provided with an opening that exposes a region where wire bonding or the like of the source electrode 41 is performed. Further, the entire region of the gate wiring 42w is covered with the moisture-resistant insulating film 8, but an opening is provided in the moisture-resistant insulating film 8 in a region where wire bonding or the like of the gate pad 42p is performed.

[Second Variation]

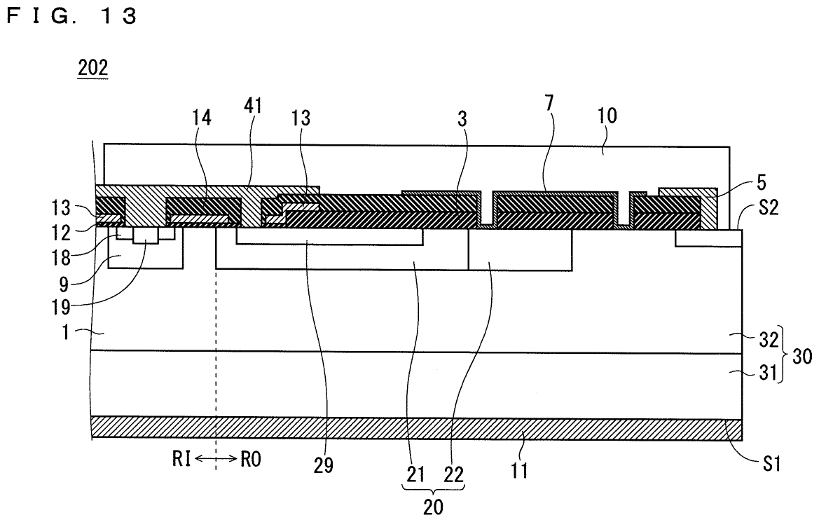

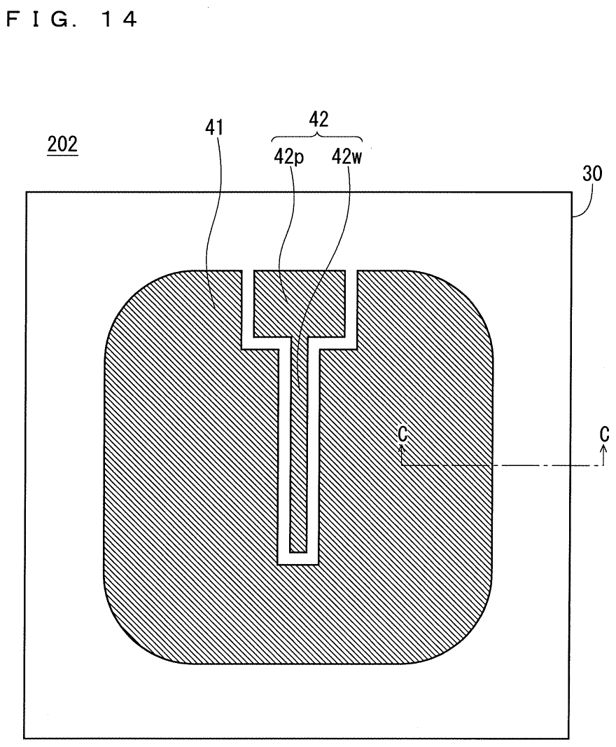

FIG. 13 is a partial cross-sectional view illustrating a configuration of a MOSFET 202 which is a semiconductor device according to a second variation of the second preferred embodiment. FIG. 14 is a plan view of the MOSFET 202, and a cross-sectional view taken along line C-C in FIG. 14 as viewed from an arrow corresponds to FIG. 13. In FIG. 14, only the source electrode 41 and the gate wiring electrode 42 in an upper surface configuration of the MOSFET 202 are illustrated for convenience. Unlike the MOSFET 200 illustrated in FIG. 10, the MOSFET 202 illustrated in FIG. 14 is provided such that the gate wiring 42w does not surround the source electrode 41 and enters a recess deeply formed on one side of the rectangular source electrode 41 in plan view.

Also in the MOSFET 202, the semi-insulating film 7 is provided on at least a part of the field insulating film 3 and the interlayer insulating film 14 in the outer region RO. The semi-insulating film 7 is separated from the source electrode 41, the gate wiring electrode 42, and the outer peripheral electrode 5 so as not to be in contact with the source electrode 41, the gate wiring electrode 42 (not illustrated in FIG. 13), and the outer peripheral electrode 5. Further, the semi-insulating film 7 is connected to the front surface S2 of the epitaxial substrate 30 on the termination well region 20 and in a region outside the termination well region 20 via an opening portion formed in the field insulating film 3 and the interlayer insulating film 14.

[Third Variation]

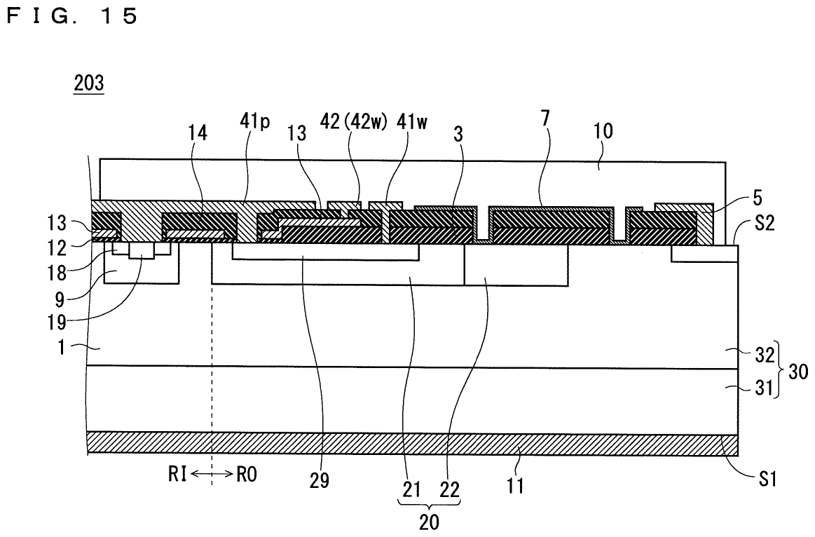

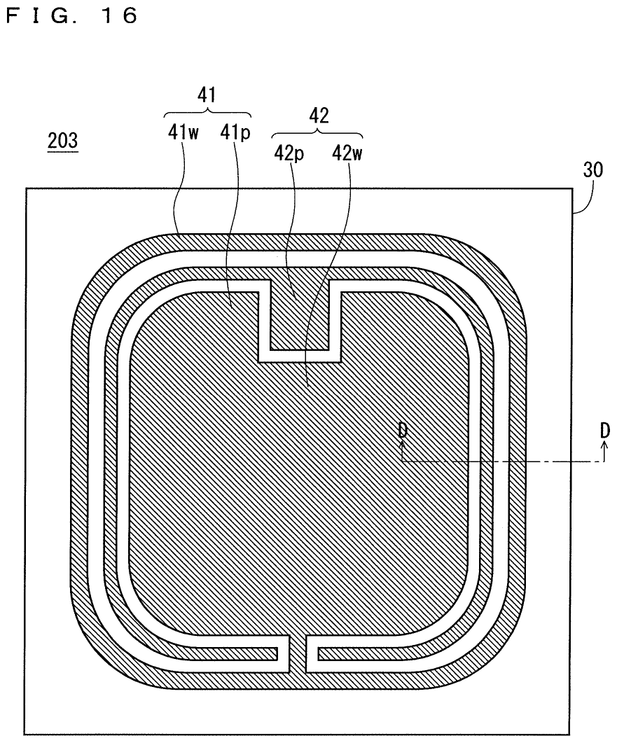

FIG. 15 is a partial cross-sectional view illustrating a configuration of a MOSFET 203 which is a semiconductor device according to a third variation of the second preferred embodiment. FIG. 16 is a plan view of the MOSFET 203, and a cross-sectional view taken along line D-D in FIG. 16 as viewed from an arrow corresponds to FIG. 15. In FIG. 16, only the source electrode 41 and the gate wiring electrode 42 in the upper surface configuration of the MOSFET 203 are illustrated for convenience.

In the MOSFET 203 illustrated in FIG. 16, the source electrode 41 includes a source pad 41p having a rectangular shape in plan view, and a source wiring 41w which is a surface wiring formed so as to surround the gate wiring electrode 42 including the gate wiring 42w. Note that, in the MOSFET 203 illustrated in FIG. 16, the gate wiring 42w is opened on a plane, and the source wiring 41w and the source pad 41p are directly connected at an opening portion of the gate wiring 42w. However, the source wiring 41w and the source pad 41p may be separated from each other, and may be electrically connected by providing a conductive film other than the source electrode 41, the gate wiring electrode 42, and the gate electrode 13, or may be electrically connected via the termination contact region 29.

Also in the MOSFET 203, the semi-insulating film 7 is provided on at least a part of the field insulating film 3 and the interlayer insulating film 14 in the outer region RO. The semi-insulating film 7 is separated from the source electrode 41, the gate wiring electrode 42, and the outer peripheral electrode 5 without being in contact with them. Further, the semi-insulating film 7 is connected to the front surface S2 of the epitaxial substrate 30 through an opening portion formed in the field insulating film 3 and the interlayer insulating film 14 on each of the termination well region 20 and a region outside the termination well region 20.

[Fourth Variation]

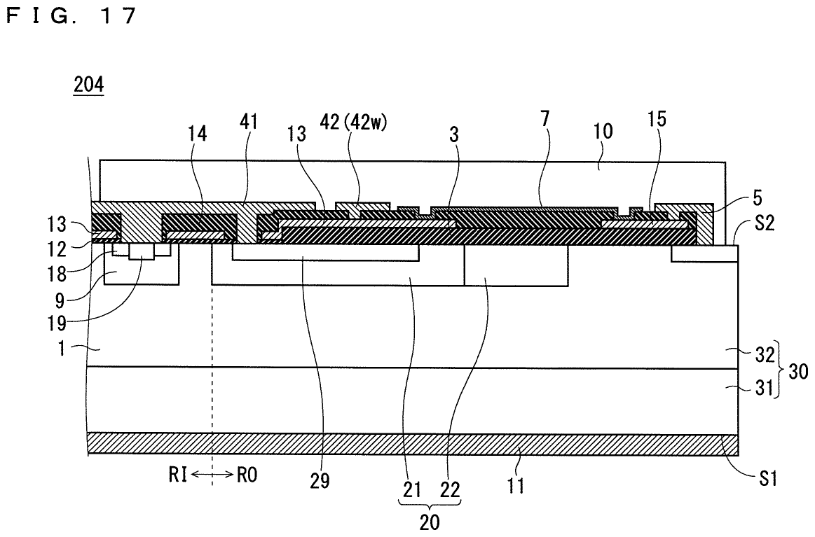

FIG. 17 is a partial cross-sectional view illustrating a configuration of a MOSFET 204 which is a semiconductor device according to a fourth variation of the second preferred embodiment. In the MOSFET 204 of FIG. 17, an outer peripheral end of the gate electrode 13 is located outside an outer peripheral end of the gate wiring electrode 42. Further, on the field insulating film 3, an outer peripheral extraction electrode 15 connected to the outer peripheral electrode 5 through an opening portion formed in the interlayer insulating film 14 is provided. An inner peripheral end of the outer peripheral extraction electrode 15 is located inside an inner peripheral end of the outer peripheral electrode 5. The semi-insulating film 7 is not connected to the front surface S2 of the epitaxial substrate 30, but is connected to the gate electrode 13 and the outer peripheral extraction electrode 15 via an opening portion formed in the interlayer insulating film 14.

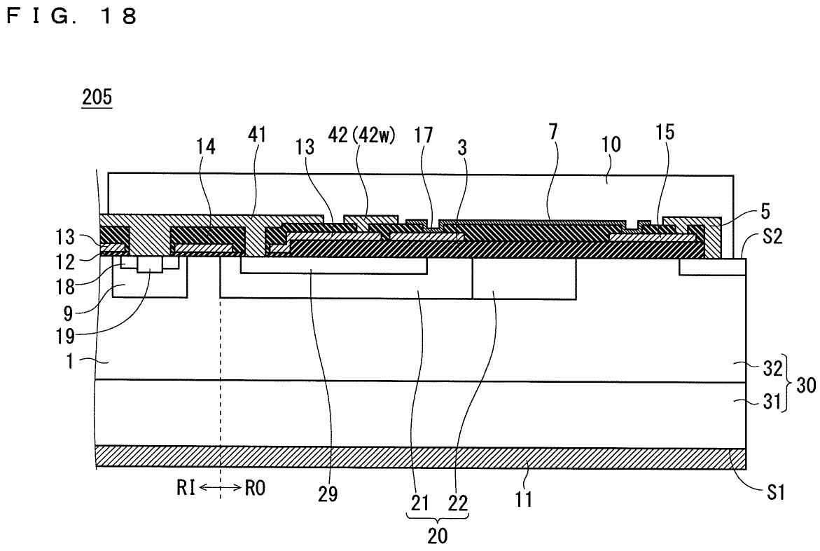

As in a MOSFET 205 illustrated in FIG. 18, the semi-insulating film 7 may be connected to an inner peripheral extraction electrode 17 provided on the field insulating film 3 in a manner separated from the gate electrode 13 through an opening portion formed in the interlayer insulating film 14 without being connected to the gate electrode 13. The inner peripheral extraction electrode 17 is connected to the source electrode 41 through an opening formed in the interlayer insulating film 14 in a region (not illustrated), and is led to a region outside the gate electrode 13 in a planar manner. Further, the inner peripheral extraction electrode 17 may be connected to the termination well region 20 through an opening portion formed in the field insulating film 3 without being connected to the source electrode 41.

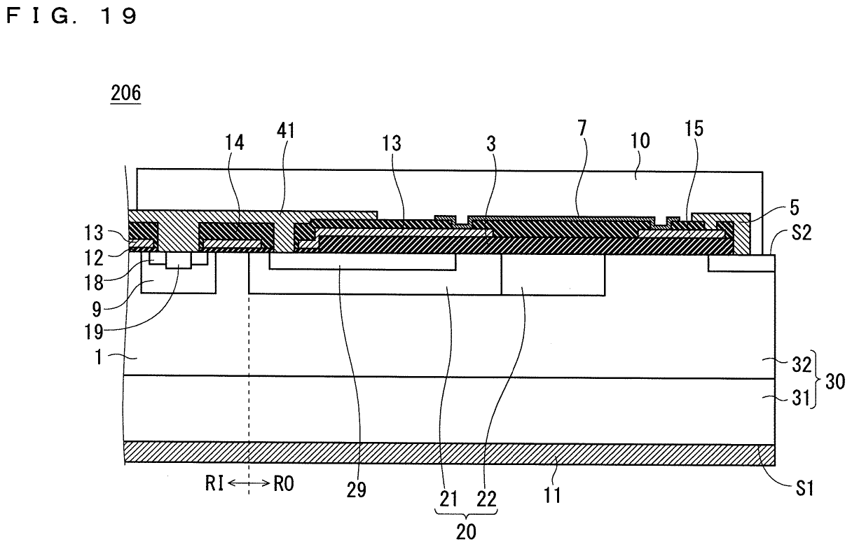

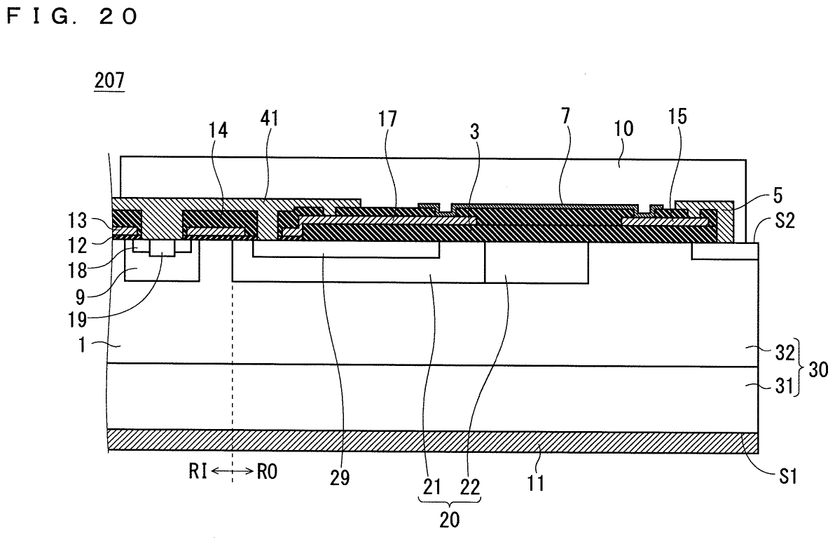

Note that, in the MOSFET 204 and the MOSFET 205 illustrated as the fourth variation, the gate wiring 42w is provided so as to surround the source electrode 41, similarly to a plan view of the MOSFET 200 illustrated in FIG. 10. However, similarly to the plan view of the MOSFET 202 illustrated in FIG. 14, the gate wiring 42w may not surround the source electrode 41 and may be provided so as to enter a recess formed deep on one side of the rectangular source electrode 41 in plan view. In this case, as in the MOSFET 206 illustrated in FIG. 19, the semi-insulating film 7 is connected to the gate electrode 13 through an opening portion formed in the interlayer insulating film 14 outside the source electrode 41. Further, as in a MOSFET 207 illustrated in FIG. 20, the inner peripheral extraction electrode 17 connected to the source electrode 41 through an opening portion formed in the interlayer insulating film 14 may be provided on the field insulating film 3, and the semi-insulating film 7 may be connected to the inner peripheral extraction electrode 17 through an opening portion formed in the interlayer insulating film 14 outside the source electrode 41.

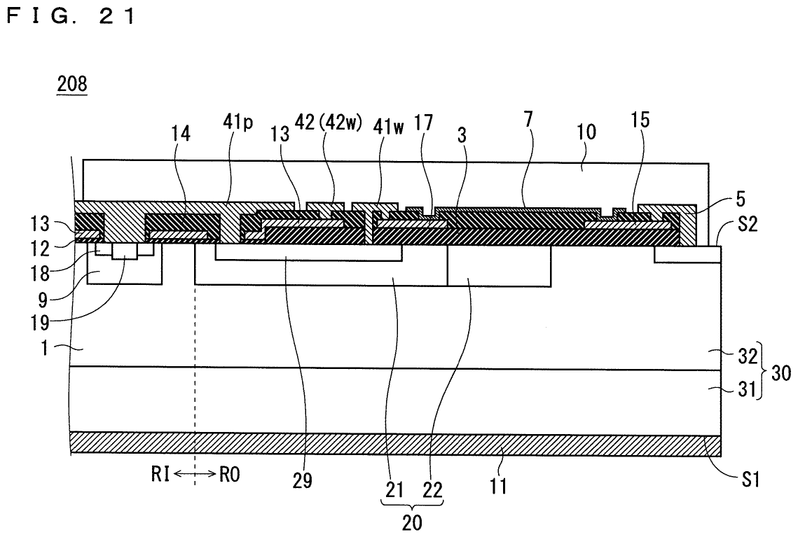

Further, similarly to the plan view of the MOSFET 203 illustrated in FIG. 16, the source wiring 41w surrounding the gate wiring electrode 42 including the gate wiring 42w may be formed. In this case, as in a MOSFET 208 illustrated in FIG. 21, the inner peripheral extraction electrode 17 connected to the source wiring 41w through an opening portion formed in the interlayer insulating film 14 may be provided on the field insulating film 3, and the semi-insulating film 7 is connected to the inner peripheral extraction electrode 17 through an opening portion formed in the interlayer insulating film 14 outside the source wiring 41w.

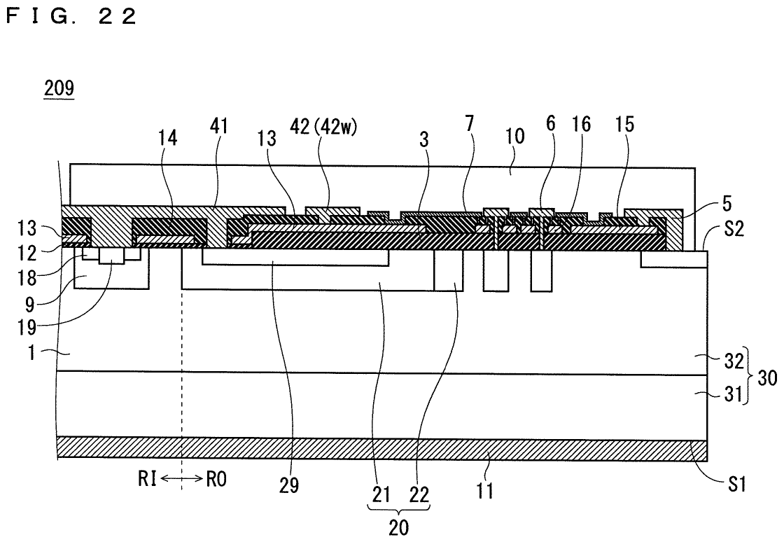

Further, similarly to the SBD 101 illustrated in FIG. 3, the low concentration region 22 of the termination well region 20 may be divided into a plurality of regions. In a MOSFET 209 illustrated in FIG. 22, a plurality of auxiliary electrodes 6 connected to a plurality of the low concentration regions 22 through an opening portion formed in the interlayer insulating film 14 and the field insulating film 3 are formed on the interlayer insulating film 14. Further, an auxiliary extraction electrode 16 is formed on the field insulating film 3 around each of the auxiliary electrodes 6. The auxiliary extraction electrode 16 is formed so as to partially protrude from below the auxiliary electrode 6, and the auxiliary electrode 6 is connected to the auxiliary extraction electrodes 16 on both sides through an opening portion formed in the interlayer insulating film 14. The semi-insulating film 7 is not connected to the auxiliary electrode 6, but is connected to the auxiliary extraction electrode 16 through an opening portion provided in the interlayer insulating film 14. Therefore, the auxiliary extraction electrode 16 is connected to the semi-insulating film 7 and the auxiliary electrode 6 through an opening portion formed in the interlayer insulating film 14. Further, the semi-insulating film 7 and the auxiliary electrode 6 are connected via the auxiliary extraction electrode 16.

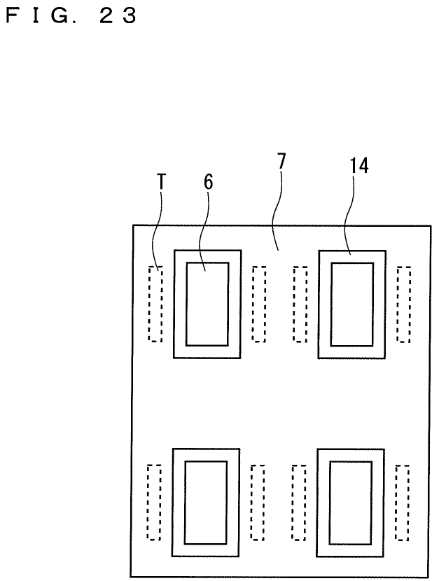

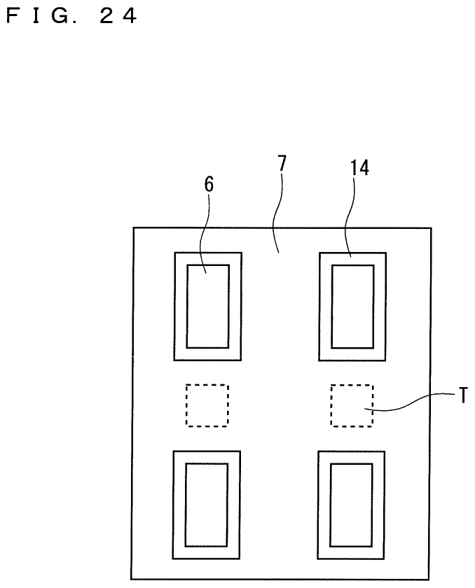

The auxiliary electrode 6 may not be formed continuously on each of the low concentration regions 22, and may be formed intermittently (partially discontinuously). FIGS. 23 and 24 are partial plan views illustrating a configuration example of the vicinity of the auxiliary electrode 6 in a case where the auxiliary electrode 6 has an intermittent shape. The vertical direction in FIGS. 23 and 24 corresponds to the depth direction in FIG. 22. FIGS. 23 and 24 illustrate an opening portion T of the interlayer insulating film 14 provided for connecting the semi-insulating film 7 and the auxiliary extraction electrode 16.

As illustrated in FIG. 23, the semi-insulating film 7 may be formed in a region where the auxiliary electrode 6 is disconnected, that is, in a region where the auxiliary electrodes 6 on the same low concentration region 22 are separated from each other. Further, as illustrated in FIG. 24, the opening portion T for connecting the semi-insulating film 7 and the auxiliary extraction electrode 16 may be arranged in a region where the auxiliary electrode 6 is disconnected.

Further, the moisture-resistant insulating film 8 may be formed so as to cover the auxiliary electrode 6.

[Operation]

Operation of the MOSFET 200 according to the second preferred embodiment illustrated in FIG. 9 will be described in two states.

A first state is a state in which positive voltage equal to or higher than a threshold is applied to the gate electrode 13. Hereinafter, this state is referred to as an “ON state”. In the ON state, an inversion channel is formed in a channel region. The inversion channel is a path through which electrons as carriers flow between the source region 18 and the drift layer 1. In the ON state, when a high voltage is applied to the back surface electrode 11 with reference to the source electrode 41, current flows through the single crystal substrate 31 and the drift layer 1. Voltage between the source electrode 41 and the back surface electrode 11 at this time is referred to as on-voltage, and current flowing between the source electrode 41 and the back surface electrode 11 is referred to as on-current. The on-current flows only in the inner region RI where a channel exists, and does not flow in the outer region RO.

A second state is a state in which voltage less than a threshold is applied to the gate electrode 13. Hereinafter, this state is referred to as an “OFF state”. In the OFF state, since no inversion channel is formed in a channel region, the on-current does not flow. Therefore, when high voltage is applied between the source electrode 41 and the back surface electrode 11, the high voltage is maintained. At this time, since voltage between the gate electrode 13 and the source electrode 41 is very small with respect to voltage between the source electrode 41 and the back surface electrode 11, high voltage is also applied between the gate electrode 13 and the back surface electrode 11.

Also in the outer region RO, high voltage is applied between each of the gate wiring electrode 42 and the gate electrode 13 and the back surface electrode 11. Similarly to the case where an electrical contact with the source electrode 41 is formed in the element well region 9 in the inner region RI, an electrical contact with the source electrode 41 is formed in the termination contact region 29 in the outer region RO. For this reason, a high electric field is prevented from being applied to the gate insulating film 12 and the interlayer insulating film 14.

The outer region RO in the OFF state performs operation similar to that of the SBD 100 in the OFF state described in the first preferred embodiment. That is, a high electric field is applied near a pn junction interface between the drift layer 1 and the termination well region 20, and avalanche breakdown occurs when voltage exceeding a critical electric field is applied to the back surface electrode 11. Normally, rated voltage is determined so that the MOSFET 200 is used in a range in which avalanche breakdown does not occur.

In the OFF state, a depletion layer expands in a direction from a pn junction interface between the drift layer 1 and the element well region 9 and the termination well region 20 toward the single crystal substrate 31 (downward direction) and in an outer peripheral direction of the drift layer 1 (rightward direction).

Here, a case where the MOSFET 200 is set to the OFF state under high humidity is considered. In a case where the surface protective film 10 is made from polyimide or the like, the surface protective film 10 contains a large amount of moisture under high humidity. When the moisture reaches a surface of the source electrode 41, the gate wiring electrode 42, and the outer peripheral electrode 5, the source electrode 41 and the gate wiring electrode 42 act as a cathode and the outer peripheral electrode 5 acts as an anode by voltage applied to the MOSFET 200 in the OFF state. Even in a case where the surface protective film 10 is not formed, a large amount of moisture permeates sealing gel and reaches the MOSFET 200, and similarly, the source electrode 41 and the gate wiring electrode 42 act as a cathode and the outer peripheral electrode 5 acts as an anode. Further, in a case where voltage equal to or lower than voltage of the source electrode 41 is applied to the gate electrode 13, a relationship in which the gate wiring electrode 42 is a cathode and the source electrode 41 is an anode is also established.

The reduction reaction of oxygen and the formation reaction of hydrogen described in the first preferred embodiment occur in the vicinity of the source electrode 41 and the gate wiring electrode 42 serving as a cathode. Along with this, a concentration of hydroxide ions increases in the vicinity of the source electrode 41 and the gate wiring electrode 42. The hydroxide ions chemically react with the source electrode 41 and the gate wiring electrode 42. For example, in a case where the source electrode 41 and the gate wiring electrode 42 are made from aluminum, aluminum may become aluminum hydroxide by the chemical reaction. Further, aluminum hydroxide may become aluminum oxide depending on ambient temperature, pH, and the like.

Further, in the vicinity of the outer peripheral electrode 5 serving as an anode, for example, in a case where the outer peripheral electrode 5 is made from aluminum, aluminum dissolves as Al₃⁺ and reacts with surrounding moisture to become aluminum hydroxide or aluminum oxide.

Such a reaction similarly occurs according to polarity in a case where a relationship in which the gate wiring electrode 42 is a cathode and the source electrode 41 is an anode is established, or a relationship vice versa is established.

These aluminum hydroxides or aluminum oxides are deposited as insulating materials on a surface of the source electrode 41, the gate wiring electrode 42, and the outer peripheral electrode 5. By this deposition, a film on the source electrode 41, the gate wiring electrode 42, and the outer peripheral electrode 5 is broken or pushed up and peeled off, and when peeling progresses and a cavity portion is formed on the field insulating film 3 and the interlayer insulating film 14, moisture enters the cavity portion. The moisture that enters the cavity portion may cause excessive leakage current, aerial discharge in the cavity portion, and the like, and may cause element destruction of the MOSFET 200. Further, in a case where volume expansion occurs due to deposition of the insulating material, stress is applied to a film under the source electrode 41, the gate wiring electrode 42, and the outer peripheral electrode 5 and the epitaxial substrate 30, which may cause physical breakdown of the MOSFET 200 and cause element destruction.

The deposition reaction of aluminum hydroxide or aluminum oxide is accelerated by electric field strength. In particular, an outer peripheral end portion of the gate wiring electrode 42 and an inner peripheral end portion of the outer peripheral electrode 5 are likely to have a high electric field, and in a case where the epitaxial substrate 30 is made from silicon carbide, a higher electric field strength is generated in the outer region RO, and a deposition reaction of aluminum hydroxide or aluminum oxide is accelerated. Further, also in an outer peripheral end portion of the source electrode 41 and an inner peripheral end portion of the gate wiring electrode 42, a high electric field is generated by voltage applied to the gate wiring electrode 42, and a deposition reaction of aluminum hydroxide or aluminum oxide is accelerated.

Further, in a case where the semi-insulating film 7 is connected to an end portion of the source electrode 41, the gate wiring electrode 42, and the outer peripheral electrode 5, moisture reaches the end portion of the source electrode 41, the gate wiring electrode 42, and the outer peripheral electrode 5 through the semi-insulating film 7, and electrons are exchanged with the source electrode 41, the gate wiring electrode 42, and the outer peripheral electrode 5 through the semi-insulating film 7. Accordingly, a deposition reaction of aluminum hydroxide or aluminum oxide is further accelerated. Furthermore, due to conductivity of the semi-insulating film 7, a potential gradient is likely to occur in an outer peripheral end portion of the source electrode 41, an inner peripheral end portion and an outer peripheral end portion of the gate wiring electrode 42, and a periphery of an inner peripheral end portion of the outer peripheral electrode 5, and a deposition reaction of aluminum hydroxide or aluminum oxide due to electric field strength may also be accelerated.

Further, voltage applied to the gate wiring electrode 42 constantly changes during operation of the MOSFET 200, and the gate wiring electrode 42 repeatedly becomes an anode or a cathode with respect to the source electrode 41. At this time, electrons move back and forth between the source electrode 41 and the gate wiring electrode 42, and a deposition reaction of aluminum hydroxide or aluminum oxide may be accelerated according to a speed of the movement.

On the other hand, in the MOSFET 200 of the second preferred embodiment, the semi-insulating film 7 is separated from the source electrode 41, the gate wiring electrode 42, and the outer peripheral electrode 5 so as not to be in contact with the source electrode 41, the gate wiring electrode 42, and the outer peripheral electrode 5. In this manner, electrons are not directly exchanged between the semi-insulating film 7 and the source electrode 41, the gate wiring electrode 42, and the outer peripheral electrode 5, and a potential gradient around an outer peripheral end portion of the source electrode 41, an inner peripheral end portion and an outer peripheral end portion of the gate wiring electrode 42, and an inner peripheral end portion of the outer peripheral electrode 5 due to conductivity of the semi-insulating film 7 does not occur. As a result, deposition of aluminum hydroxide or aluminum oxide on a surface of the source electrode 41, the gate wiring electrode 42, and the outer peripheral electrode 5 can be suppressed.

Further, in the MOSFET 200 according to second preferred embodiment, the semi-insulating film 7 is connected to the front surface S2 of the epitaxial substrate 30 through an opening portion formed in the field insulating film 3 and the interlayer insulating film 14 on each of the termination well region 2 and a region outside the termination well region 2. For this reason, in the OFF state, a gentle potential gradient is formed in a region where the semi-insulating film 7 is formed. Therefore, it is possible to suppress occurrence of excessive electric field concentration around the termination well region 2.

Further, in a case where the semi-insulating film 7 is connected to the front surface S2 of the epitaxial substrate 30 in the high concentration region 21 or a region on the termination contact region 29 in the termination well region 20, a gentle potential gradient from potential closer to the source electrode 41 to potential closer to the back surface electrode 11 is formed. Therefore, it is possible to more effectively suppress occurrence of excessive electric field concentration around the termination well region 2.

The above effect can also be obtained in the MOSFETs 201 to 209 described in the first to fourth variations of the second preferred embodiment.

In the MOSFET 201 illustrated FIG. 12, the moisture-resistant insulating film 8 is formed so as to cover an outer peripheral end of the source electrode 41, the gate wiring 42w, and an inner peripheral end of the outer peripheral electrode 5. For this reason, moisture is prevented from reaching an outer peripheral end of the source electrode 41, the gate wiring 42w, and an inner peripheral end of the outer peripheral electrode 5. As a result, a deposition reaction of aluminum hydroxide or aluminum oxide at an outer peripheral end of the source electrode 41, the gate wiring 42w, and an inner peripheral end of the outer peripheral electrode 5 can be further suppressed.

In the MOSFET 202 and the MOSFET 203 illustrated in FIGS. 13 to 16, the semi-insulating film 7 is formed apart from the source electrode 41 even in a region where the source electrode 41 is located outside the gate wiring electrode 42, and a deposition reaction of aluminum hydroxide or aluminum oxide at an outer peripheral end of the source electrode 41 can be suppressed.

In the MOSFETs 204 to 208 illustrated in FIGS. 17 to 21, since the semi-insulating film 7 is not connected to the source electrode 41, the gate wiring electrode 42, and the outer peripheral electrode 5, deposition of aluminum hydroxide or aluminum oxide on a surface of the source electrode 41, the gate wiring electrode 42, and the outer peripheral electrode 5 can be suppressed. Further, since the semi-insulating film 7 is connected to the gate electrode 13 or the inner peripheral extraction electrode 17 and the outer peripheral extraction electrode 15 via an opening portion formed in the interlayer insulating film 14, a gentle potential gradient is formed in a region from potential closer to the source electrode 41 or the gate electrode 13 to potential closer to the back surface electrode 11 in the OFF state. Therefore, it is possible to suppress occurrence of excessive electric field concentration around the termination well region 20. Furthermore, since a contact hole where the semi-insulating film 7 and the front surface S2 of the epitaxial substrate 30 are connected is not formed, damage to the front surface S2 of the epitaxial substrate 30 due to over-etching can be avoided, and reliability of the semiconductor device when high voltage is applied can be enhanced.

In the MOSFET 209 illustrated in FIG. 22, since the semi-insulating film 7 is not connected to the auxiliary electrode 6, deposition of aluminum hydroxide or aluminum oxide on a surface of the auxiliary electrode 6 can be suppressed. Further, since the semi-insulating film 7 is connected to the auxiliary extraction electrode 16 via an opening portion formed in the interlayer insulating film 14, a gentle potential gradient is formed around each of the divided low concentration regions 22, and occurrence of excessive electric field concentration can be suppressed.

[Manufacturing Method]

Next, a method for manufacturing the MOSFET 200 of the second preferred embodiment will be described.

First, as in the first preferred embodiment, the single crystal substrate 31 having low resistance containing n-type impurities at a relatively high concentration (n⁺) is prepared. The single crystal substrate 31 is a SiC substrate having a polytype of 4H, and has an off angle of four degrees or eight degrees.

Next, SiC is epitaxially grown on the single crystal substrate 31 to form the epitaxial layer 32 of n type having an impurity concentration of 1×10¹⁴/cm³ or more and 1×10¹⁷/cm³ or less. As a result, the epitaxial substrate 30 including the single crystal substrate 31 and the epitaxial layer 32 is obtained.

Next, a process of forming an impurity region in an upper layer portion of the epitaxial layer 32 is repeated by combining formation of a resist mask by a photolithography process and an ion implantation process using the resist mask as an implantation mask, so that the termination well region 20, the element well region 9, the contact region 19, the source region 18, and the termination contact region 29 are formed in the upper layer portion of the epitaxial layer 32.

In the above ion implantation, nitrogen (N) or the like is used as an n-type impurity, and Al, B, or the like is used as a p-type impurity. The element well region 9 and the high concentration region 21 of the termination well region 20 can be collectively formed. Further, the contact region 19 and the termination contact region 29 can be collectively formed. Further, the termination contact region 29 and the source region 18 may be collectively formed.

An impurity concentration of the element well region 9 and the high concentration region 21 of the termination well region 20 is 1.0×10¹⁸/cm³ or more and 1.0×10²⁰/cm³ or less. An impurity concentration of the source region 18 is set to 1.0×10¹⁹/cm³ or more and 1.0×10²¹/cm³ or less, which is higher than an impurity concentration of the element well region 9. A dose amount of the low concentration region 22 of the termination well region 20 is preferably 0.5×10¹³/cm² or more and 5×10¹³/cm² or less, for example, 1.0×10¹³/cm². An impurity concentration of the contact region, the termination contact region 29, and the outer peripheral contact region 25 is set to be higher than an impurity concentration of the element well region 9.

In a case of Al, implantation energy of ion implantation is, for example, 100 keV or more and 700 keV or less. In this case, an impurity concentration of the low concentration region 22 converted from the dose amount [cm⁻²] is 1×10¹⁷/cm³ or more and 1×10¹⁹/cm³ or less. Further, in a case of N, implantation energy of ion implantation is, for example, 20 keV or more and 300 keV or less.

After the above, annealing is performed at a temperature of 1300° C. or more and 1900° C. or less for 30 seconds or more and one hour or less in an inert gas atmosphere such as argon (Ar) gas using a heat treatment apparatus. By this annealing, impurities added by ion implantation are activated.

Next, a SiO₂ film having thickness of 1 μm to be the field insulating film 3 is deposited on a surface of the epitaxial substrate 30 by, for example, a CVD method. After the above, the SiO₂ film is patterned by a photolithography process and an etching process so as to remove the SiO₂ film in the inner region RI, a partial region on the high concentration region 21 of the outer region RO, and a region where the outer peripheral electrode 5 is connected to the epitaxial substrate 30. By the above, the field insulating film 3 is formed on the front surface S2 of the epitaxial substrate 30.

Next, the front surface S2 of the epitaxial layer 32 not covered with the field insulating film 3 is thermally oxidized to form SiO₂ to be the gate insulating film 12. Then, a conductive polycrystalline silicon film to be the gate electrode 13 is formed on the gate insulating film 12 and a part of the field insulating film 3 by a low pressure CVD method. Furthermore, the gate electrode 13 is formed by patterning the polycrystalline silicon film by a photolithography process and an etching process. At this time, at the same time, the outer peripheral extraction electrode 15, the inner peripheral extraction electrode 17, and the auxiliary extraction electrode 16 can be formed.

Next, a SiO₂ film to be the interlayer insulating film 14 is formed by a CVD method. Then, by a photolithography process and an etching process, a contact hole penetrating SiO₂ and reaching each of the contact region 19 and the source region 18 is formed. At the same time, a contact hole penetrating the interlayer insulating film 14 and reaching the gate electrode 13 is formed in the outer region RO. Further, the SiO₂ film is removed from an outer peripheral portion of the epitaxial layer 32.

In an etching process of the SiO₂ film to be the interlayer insulating film 14, a contact hole for connecting the semi-insulating film 7 and the front surface S2 of the epitaxial substrate 30 is also formed at the same time. Note that, in a case where the MOSFET 209 is manufactured from the MOSFET 204 illustrated from FIGS. 17 to 24, in this process, a contact hole for connecting the semi-insulating film 7 and the front surface S2 of the epitaxial substrate 30 is not formed, and a contact hole for connecting the semi-insulating film 7 and the outer peripheral extraction electrode 15, the inner peripheral extraction electrode 17, and the auxiliary extraction electrode 16, a contact hole for connecting the source electrode 41 and the inner peripheral extraction electrode 17, a contact hole for connecting the outer peripheral electrode 5 and the outer peripheral extraction electrode 15, and a contact hole for connecting the auxiliary electrode 6 and the auxiliary extraction electrode 16 are formed.

The interlayer insulating film 14 may be configured to cover the field insulating film 3. Further, an opening provided in the field insulating film 3 for connecting the outer peripheral electrode 5 to the epitaxial substrate 30 may be formed when the interlayer insulating film 14 is patterned. Further, the field insulating film 3 and the interlayer insulating film 14 may be formed in the same process, and the field insulating film 3 and the interlayer insulating film 14 may be an integrated film.

Next, a material layer to be the source electrode 41, the gate wiring electrode 42, and the outer peripheral electrode 5 is formed on the front surface S2 of the epitaxial substrate 30 by a sputtering method, an evaporation method, or the like, and the material layer is patterned by a photolithography process and an etching process. Further, in a case where the MOSFET 209 illustrated in FIG. 22 is manufactured, the auxiliary electrode 6 can be formed at the same time in this process. As a material layer to be the source electrode 41, the gate wiring electrode 42, the outer peripheral electrode 5, and the auxiliary electrode 6, for example, metal containing one or more of Ti, Ni, Al, Cu, and Au, an Al alloy such as Al—Si, or the like is used. A silicide film may be formed in advance by heat treatment in a portion of the epitaxial substrate 30 in contact with such a material layer.

Next, in a case where the moisture-resistant insulating film 8 is formed as in the MOSFET 201 of FIG. 12, a SiN film is formed by, for example, plasma CVD, and a SiN film is patterned by a photolithography process and an etching process to form the moisture-resistant insulating film 8. Then, for example, a SInSiN film to be the semi-insulating film 7 is formed by plasma CVD, and patterning is performed by a photolithography process and an etching process to form the semi-insulating film 7. Further, in the formation of the semi-insulating film 7, the semi-insulating film 7 may have a laminated structure by formation of a SiN film having high moisture resistance and high insulation on the SInSiN film.

Next, for example, photosensitive polyimide is applied so as to cover the source electrode 41, the gate wiring electrode 42, the outer peripheral electrode 5, the field insulating film 3, the interlayer insulating film 14, the semi-insulating film 7, the moisture-resistant insulating film 8, and the front surface S2 of the epitaxial substrate 30, and the surface protective film 10 having a predetermined pattern is formed by a photolithography process. Note that, in a case where the MOSFET 200 is used by being covered with sealing gel having a low elastic modulus such as silicone gel, formation of the surface protective film 10 may be omitted.

After the above, the back surface electrode 11 is formed on the back surface S1 of the epitaxial substrate 30 by, for example, a sputtering method, so that the configuration of the MOSFET 200 illustrated in FIG. 11 is obtained.

Note that the back surface electrode 11 may be formed before or after a process of forming the source electrode 41, the gate wiring electrode 42, and the outer peripheral electrode 5. As a material of the back surface electrode 11, metal or the like containing one or a plurality of Ti, Ni, Al, Cu, and Au can be used. Thickness of the back surface electrode 11 is preferably 50 nm or more and 2 μm or less, and for example, the back surface electrode 11 may be formed of a two-layer film (Ti/Au) of Ti and Au each having thickness of 1 μm or less.

[Conclusion]

According to the configuration of the second preferred embodiment and the variations of the second preferred embodiment, deposition of an insulating material on an end portion of the source electrode 41, the gate wiring electrode 42, and the outer peripheral electrode 5 is suppressed. Further, it is possible to suppress excessive electric field concentration by making a potential gradient of a termination region gentle, and to enhance insulation reliability of a MOSFET.

### Third Preferred Embodiment

In a third preferred embodiment, an example in which the semiconductor devices according to the first and second preferred embodiments described above are applied to a power conversion apparatus will be described. Here, a case where the semiconductor devices according to the first and second preferred embodiments are applied to a three-phase inverter as a power conversion apparatus will be described.

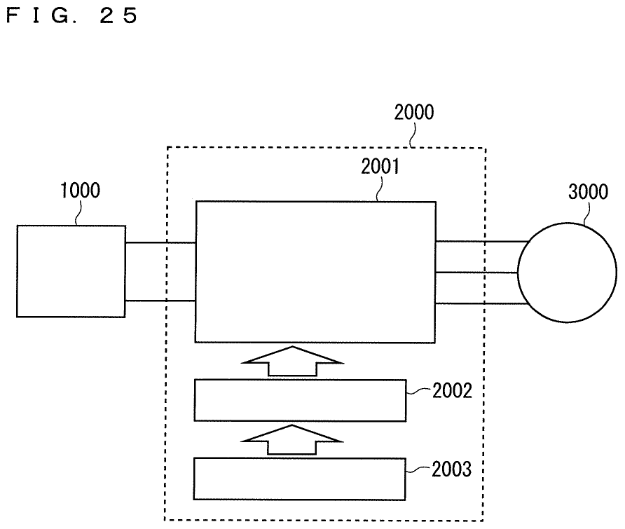

FIG. 25 is a block diagram schematically illustrating a configuration of a power conversion system to which a power conversion apparatus 2000 according to the third preferred embodiment is applied.

The power conversion system illustrated in FIG. 25 includes a power supply 1000, the power conversion apparatus 2000, and a load 3000. The power supply 1000 is a DC power supply, and supplies DC power to the power conversion apparatus 2000. The power supply 1000 can include various components, and can include, for example, a DC system, a solar cell, and a storage battery, and may include a rectifier circuit or an AC/DC converter connected to an AC system. Further, the power supply 1000 may include a DC/DC converter that converts DC power output from a DC system into predetermined power.

The power conversion apparatus 2000 is a three-phase inverter connected between the power supply 1000 and the load 3000, converts DC power supplied from the power supply 1000 into AC power, and supplies the AC power to the load 3000. As illustrated in FIG. 25, the power conversion apparatus 2000 includes a main conversion circuit 2001 that converts DC power into AC power and outputs the AC power, a drive circuit 2002 that outputs a drive signal for driving each switching element of the main conversion circuit 2001, and a control circuit 2003 that outputs a control signal for controlling the drive circuit 2002 to the drive circuit 2002.

The load 3000 is a three-phase electric motor driven by AC power supplied from the power conversion apparatus 2000. Note that the load 3000 is not limited to a specific application, but is an electric motor mounted on various electric devices, and is used as an electric motor for a hybrid vehicle, an electric vehicle, a railway vehicle, an elevator, or an air conditioner, for example.

Hereinafter, details of the power conversion apparatus 2000 will be described. The main conversion circuit 2001 includes a switching element and a freewheeling diode (not illustrated), converts DC power supplied from the power supply 1000 into AC power by switching of the switching element, and supplies the AC power to the load 3000. Although there are various specific circuit configurations of the main conversion circuit 2001, the main conversion circuit 2001 according to the present preferred embodiment is a two-level three-phase full bridge circuit, and can include six switching elements and six freewheeling diodes connected in anti-parallel to the switching elements. The semiconductor device according to the above-described first or second preferred embodiment is applied to at least one of the switching elements and the freewheeling diodes of the main conversion circuit 2001. Every two of the six switching elements are connected in series to constitute upper and lower arms, and each of the upper and lower arms constitutes each phase (U-phase, V-phase, W-phase) of a full bridge circuit. Then, an output terminal of the upper and lower arms, that is, three output terminals of the main conversion circuit 2001 are connected to the load 3000.

The drive circuit 2002 generates a drive signal for driving a switching element of the main conversion circuit 2001, and supplies the drive signal to a control electrode of the switching element of the main conversion circuit 2001. Specifically, in accordance with a control signal from the control circuit 2003 to be described later, a drive signal for setting the switching element to an ON state and a drive signal for setting the switching element to an OFF state are output to a control electrode of each switching element. In a case where the switching element is maintained to be in the ON state, the drive signal is a voltage signal (ON signal) larger than threshold voltage of the switching element, and in a case where the switching element is maintained to be in the OFF state, the drive signal is a voltage signal (OFF signal) smaller than threshold voltage of the switching element.

The control circuit 2003 controls a switching element of the main conversion circuit 2001 so that desired power is supplied to the load 3000. Specifically, time (ON time) during which each switching element of the main conversion circuit 2001 is to be in the ON state is calculated based on power to be supplied to the load 3000. For example, the main conversion circuit 2001 can be controlled by pulse width modulation (PWM) control for modulating the ON time of the switching element according to voltage to be output. Then, a control command (control signal) is output to the drive circuit 2002 so that an ON signal is output to a switching element to be in the ON state at each time point, and an OFF signal is output to a switching element to be in the OFF state at each time point. The drive circuit 2002 outputs the ON signal or the OFF signal as a drive signal to a control electrode of each switching element according to the control signal.

In the power conversion apparatus according to the present preferred embodiment, the semiconductor device according to the first preferred embodiment can be applied as a freewheeling diode of the main conversion circuit 2001, and the semiconductor device according to the second preferred embodiment can be applied as a switching element. Further, in a case where the semiconductor device according to the first and second preferred embodiments is applied to the power conversion apparatus 2000 as described above, the semiconductor device is usually embedded in gel, resin, or the like and used, but these materials also cannot completely block moisture, and insulation protection of the semiconductor device is maintained by the configurations described in the first and second preferred embodiments. In this manner, improvement in reliability can be achieved.

In the present preferred embodiment, an example in which the power conversion apparatus to which the semiconductor device according to the first and second preferred embodiments is applied is a two-level three-phase inverter is described, but the semiconductor device according to the first and second preferred embodiments can be applied to various power conversion apparatuses. For example, the power conversion apparatus may be a multi-level apparatus such as a three-level apparatus. In a case where power is supplied to a single-phase load, the power conversion apparatus may be a single-phase inverter. In a case where power is supplied to a DC load or the like, the power conversion apparatus may be a DC/DC converter or an AC/DC converter.

Further, the power conversion apparatus to which the semiconductor device according to the first and second preferred embodiments is applied is not limited to a power conversion apparatus using an electric motor as a load. For example, the power conversion apparatus can also be used as a power supply apparatus for an electric discharge machine, a laser machine, an induction heating cooker, or a noncontact power supply system, and can also be used as a power conditioner for a solar power generation system, a power storage system, or the like.

Note that, preferred embodiments can be freely combined with each other, and each preferred embodiment can be appropriately modified or omitted. For example, the high concentration region 21 and the termination contact region 29 described in the second preferred embodiment may be provided in the termination well region 2 of the semiconductor device described in the first preferred embodiment, or a laminated structure of the moisture-resistant insulating film 8 and the semi-insulating film 7 described in the first preferred embodiment may be provided in the semiconductor device described in the second preferred embodiment.

The above description is illustrative in all aspects, and it is understood that numerous variations not illustrated can be assumed. For example, it is also conceivable to modify, add or omit any constituent element, and to extract at least one constituent element in at least one preferred embodiment and combine the constituent element with a constituent element in another preferred embodiment.

Further, as long as no contradiction arises, “one” constituent element that is described to be included in each of the above preferred embodiments may be included as “one or more” constituent elements. Furthermore, a constituent element constituting the technique according to the present disclosure is a conceptual unit, and one constituent element may include a plurality of structures, and one constituent element may be a part of a certain structure. Further, a constituent element of the technique according to the present disclosure includes a structure having another configuration or shape as long as the structure exhibits the same function as the constituent element.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor layer of a first conductivity type;
a field insulating film formed on a front surface of the semiconductor layer;
a front surface electrode which is an inner peripheral electrode formed on a front surface of the semiconductor layer inside the field insulating film and covering an inner peripheral end of the field insulating film;
an outer peripheral electrode formed on a front surface of the semiconductor layer outside the field insulating film and covering an outer peripheral end of the field insulating film;
a well region of a second conductivity type formed in a surface layer portion of the semiconductor layer, connected to the front surface electrode, and extending to an outside of an outer peripheral end of the front surface electrode;
a semi-insulating film that covers a part of the field insulating film and is formed apart from the front surface electrode and the outer peripheral electrode; and
a back surface electrode formed on a back surface side of the semiconductor layer,
wherein the semi-insulating film is connected to the semiconductor layer through an opening formed in the field insulating film in each of a region inside and a region outside an outer peripheral end of the well region.

2. The semiconductor device according to claim 1, further comprising a moisture-resistant insulating film covering a part of the field insulating film and covering an outer peripheral end of the front surface electrode.

3. The semiconductor device according to claim 1, further comprising a moisture-resistant insulating film covering a part of the field insulating film and covering an inner peripheral end of the outer peripheral electrode.

4. The semiconductor device according to claim 3, wherein the moisture-resistant insulating film covers an entire front surface of the outer peripheral electrode.

5. The semiconductor device according to claim 2, wherein a part of the semi-insulating film covers the moisture-resistant insulating film.

6. The semiconductor device according to claim 3, wherein a part of the semi-insulating film covers the moisture-resistant insulating film.

7. The semiconductor device according to claim 1, wherein
the well region has a high concentration region in a surface layer portion, and
the semi-insulating film is connected to the well region via the high concentration region.

8. The semiconductor device according to claim 1, wherein
the well region is formed by being divided into a plurality of regions, and
the semi-insulating film is connected to each of a plurality of the well regions through an opening formed in the field insulating film.

9. The semiconductor device according to claim 1, wherein the semi-insulating film is connected to the semiconductor layer through an opening formed in the field insulating film so as to extend to an inside and an outside of an outer peripheral end of the well region.

10. The semiconductor device according to claim 1, wherein the semiconductor layer is formed of a wide band gap semiconductor.

11. The semiconductor device according to claim 10, wherein the wide band gap semiconductor is silicon carbide.

12. A power conversion apparatus comprising:
a conversion circuit that includes the semiconductor device according to claim 1 and converts and outputs input power;
a drive circuit that outputs a drive signal for driving the semiconductor device to the semiconductor device; and
a control circuit that outputs a control signal for controlling the drive circuit to the drive circuit.

13. A method for manufacturing the semiconductor device according to claim 2, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

14. A method for manufacturing the semiconductor device according to claim 3, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

15. A method for manufacturing the semiconductor device according to claim 5, the method comprising:
a step of forming the semi-insulating film so as to cover the moisture-resistant insulating film; and
an etching step of etching both the semi-insulating film and the moisture-resistant insulating film using a same etching mask to form an opening that penetrates both the semi-insulating film and the moisture-resistant insulating film and exposes a part of the outer peripheral electrode and the front surface electrode.

16. A method for manufacturing the semiconductor device according to claim 5, the method comprising:
a step of forming the semi-insulating film so as to cover the moisture-resistant insulating film; and
an etching step of etching both the semi-insulating film and the moisture-resistant insulating film using a same etching mask to form an opening that penetrates both the semi-insulating film and the moisture-resistant insulating film and exposes a part of the field insulating film and the front surface electrode.

17. A semiconductor device comprising:
a semiconductor layer of a first conductivity type;
a field insulating film formed on a front surface of the semiconductor layer;
an interlayer insulating film formed on a front surface of the semiconductor layer inside the field insulating film and on the field insulating film;
an inner peripheral electrode covering the interlayer insulating film, the inner peripheral electrode being formed on a front surface of the semiconductor layer and including a front surface electrode and a control wiring electrode apart from the front surface electrode;
an outer peripheral electrode formed on a front surface of the semiconductor layer outside the field insulating film and the interlayer insulating film, and covering an outer peripheral end of at least one of the field insulating film and the interlayer insulating film;
a well region of a second conductivity type formed in a surface layer portion of the semiconductor layer, connected to the front surface electrode, and extending to an outside of an outer peripheral end of the inner peripheral electrode;
a semi-insulating film that covers a part of at least one of the field insulating film and the interlayer insulating film, and is formed apart from the inner peripheral electrode and the outer peripheral electrode; and
a back surface electrode formed on a back surface side of the semiconductor layer,
wherein the semi-insulating film is connected to the semiconductor layer through an opening formed in the field insulating film in each of a region inside and a region outside an outer peripheral end of the well region.

18. The semiconductor device according to claim 17, further comprising a moisture-resistant insulating film covering a part of the field insulating film and covering an inner peripheral end and an outer peripheral end of the control wiring electrode.

19. The semiconductor device according to claim 17, further comprising a moisture-resistant insulating film covering a part of the field insulating film and covering an outer peripheral end of the front surface electrode.

20. The semiconductor device according to claim 17, further comprising a moisture-resistant insulating film covering a part of the field insulating film and covering an inner peripheral end of the outer peripheral electrode.

21. The semiconductor device according to claim 20, wherein the moisture-resistant insulating film covers an entire front surface of the outer peripheral electrode.

22. The semiconductor device according to claim 18, wherein a part of the semi-insulating film covers the moisture-resistant insulating film.

23. The semiconductor device according to claim 19, wherein a part of the semi-insulating film covers the moisture-resistant insulating film.

24. The semiconductor device according to claim 20, wherein a part of the semi-insulating film covers the moisture-resistant insulating film.

25. The semiconductor device according to claim 17, wherein
the well region has a high concentration region in a surface layer portion, and
the semi-insulating film is connected to the well region via the high concentration region.

26. The semiconductor device according to claim 17, wherein
the well region is formed by being divided into a plurality of regions, and
the semi-insulating film is connected to each of a plurality of the well regions through an opening formed in the field insulating film.

27. The semiconductor device according to claim 17, wherein the semi-insulating film is connected to the semiconductor layer through an opening formed in the field insulating film so as to extend to an inside and an outside of an outer peripheral end of the well region.

28. The semiconductor device according to claim 17,
wherein the well region is formed by being divided into a plurality of regions,
the semiconductor device further comprising:
a plurality of auxiliary electrodes formed on the interlayer insulating film and connected to each of a plurality of the well regions through an opening formed in the interlayer insulating film and the field insulating film; and
an auxiliary extraction electrode formed on the field insulating film so as to partially protrude from below the auxiliary electrode, the auxiliary extraction electrode being connected to the semi-insulating film and the auxiliary electrode through an opening formed in the interlayer insulating film,
wherein the semi-insulating film and the auxiliary electrode are connected via the auxiliary extraction electrode.

29. The semiconductor device according to claim 28, further comprising a moisture-resistant insulating film covering the auxiliary electrode.

30. The semiconductor device according to claim 17, wherein the semiconductor layer is formed of a wide band gap semiconductor.

31. The semiconductor device according to claim 30, wherein the wide band gap semiconductor is silicon carbide.

32. A power conversion apparatus comprising:
a conversion circuit that includes the semiconductor device according to claim 17 and converts and outputs input power;
a drive circuit that outputs a drive signal for driving the semiconductor device to the semiconductor device; and
a control circuit that outputs a control signal for controlling the drive circuit to the drive circuit.

33. A method for manufacturing the semiconductor device according to claim 18, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

34. A method for manufacturing the semiconductor device according to claim 19, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

35. A method for manufacturing the semiconductor device according to claim 20, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

36. A method for manufacturing the semiconductor device according to claim 22, the method comprising:
a step of forming the semi-insulating film so as to cover the moisture-resistant insulating film; and
an etching step of etching both the semi-insulating film and the moisture-resistant insulating film using a same etching mask to form an opening that penetrates both the semi-insulating film and the moisture-resistant insulating film and exposes a part of the outer peripheral electrode and the front surface electrode.

37. A method for manufacturing the semiconductor device according to claim 22, the method comprising:
a step of forming the semi-insulating film so as to cover the moisture-resistant insulating film; and
an etching step of etching both the semi-insulating film and the moisture-resistant insulating film using a same etching mask to form an opening that penetrates both the semi-insulating film and the moisture-resistant insulating film and exposes a part of the field insulating film and the front surface electrode.

38. A semiconductor device comprising:
a semiconductor layer of a first conductivity type;
a field insulating film formed on a front surface of the semiconductor layer;
an interlayer insulating film formed on a front surface of the semiconductor layer inside the field insulating film and on the field insulating film;
an inner peripheral electrode covering the interlayer insulating film, the inner peripheral electrode being formed on a front surface of the semiconductor layer and including a front surface electrode and a control wiring electrode apart from the front surface electrode;
an outer peripheral electrode formed on a front surface of the semiconductor layer outside the field insulating film and the interlayer insulating film, and covering an outer peripheral end of at least one of the field insulating film and the interlayer insulating film;
a well region of a second conductivity type formed in a surface layer portion of the semiconductor layer, connected to the front surface electrode, and extending to an outside of an outer peripheral end of the inner peripheral electrode;
an inner peripheral extraction electrode formed on the field insulating film, connected to the inner peripheral electrode through an opening formed in the interlayer insulating film, and extending to an outside of the inner peripheral electrode;
an outer peripheral extraction electrode formed on the field insulating film, connected to the outer peripheral electrode through an opening formed in the interlayer insulating film, and extending to an inner periphery of the outer peripheral electrode;
a semi-insulating film that covers a part of the interlayer insulating film, and is formed apart from the inner peripheral electrode and the outer peripheral electrode; and
a back surface electrode formed on a back surface side of the semiconductor layer,
wherein the semi-insulating film is connected to the inner peripheral extraction electrode and the outer peripheral extraction electrode through an opening formed in the interlayer insulating film.

39. The semiconductor device according to claim 38, further comprising a moisture-resistant insulating film covering a part of the field insulating film and covering an inner peripheral end and an outer peripheral end of the control wiring electrode.

40. The semiconductor device according to claim 38, further comprising a moisture-resistant insulating film covering a part of the field insulating film and covering an outer peripheral end of the front surface electrode.

41. The semiconductor device according to claim 38, further comprising a moisture-resistant insulating film covering a part of the field insulating film and covering an inner peripheral end of the outer peripheral electrode.

42. The semiconductor device according to claim 41, wherein the moisture-resistant insulating film covers an entire front surface of the outer peripheral electrode.

43. The semiconductor device according to claim 39, wherein a part of the semi-insulating film covers the moisture-resistant insulating film.

44. The semiconductor device according to claim 40, wherein a part of the semi-insulating film covers the moisture-resistant insulating film.

45. The semiconductor device according to claim 41, wherein a part of the semi-insulating film covers the moisture-resistant insulating film.

46. The semiconductor device according to claim 38, wherein
the well region has a high concentration region in a surface layer portion, and
the semi-insulating film is connected to the well region via the high concentration region.

47. The semiconductor device according to claim 38, wherein
the well region is formed by being divided into a plurality of regions, and
the semi-insulating film is connected to each of a plurality of the well regions through an opening formed in the field insulating film.

48. The semiconductor device according to claim 38, wherein the semi-insulating film is connected to the semiconductor layer through an opening formed in the field insulating film so as to extend to an inside and an outside of an outer peripheral end of the well region.

49. The semiconductor device according to claim 38,
wherein the well region is formed by being divided into a plurality of regions,
the semiconductor device further comprising:
a plurality of auxiliary electrodes formed on the interlayer insulating film and connected to each of a plurality of the well regions through an opening formed in the interlayer insulating film and the field insulating film; and
an auxiliary extraction electrode formed on the field insulating film so as to partially protrude from below the auxiliary electrode, the auxiliary extraction electrode being connected to the semi-insulating film and the auxiliary electrode through an opening formed in the interlayer insulating film,
wherein the semi-insulating film and the auxiliary electrode are connected via the auxiliary extraction electrode.

50. The semiconductor device according to claim 49, further comprising a moisture-resistant insulating film covering the auxiliary electrode.

51. The semiconductor device according to claim 38, wherein the semiconductor layer is formed of a wide band gap semiconductor.

52. The semiconductor device according to claim 51, wherein the wide band gap semiconductor is silicon carbide.

53. A power conversion apparatus comprising:
a conversion circuit that includes the semiconductor device according to claim 38 and converts and outputs input power;
a drive circuit that outputs a drive signal for driving the semiconductor device to the semiconductor device; and
a control circuit that outputs a control signal for controlling the drive circuit to the drive circuit.

54. A method for manufacturing the semiconductor device according to claim 39, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

55. A method for manufacturing the semiconductor device according to claim 40, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

56. A method for manufacturing the semiconductor device according to claim 41, the method comprising:
a step of forming the moisture-resistant insulating film so as to cover the front surface electrode, the outer peripheral electrode, and the field insulating film; and
a step of etching both the moisture-resistant insulating film and the field insulating film using a same etching mask to form an opening that penetrates both the moisture-resistant insulating film and the field insulating film and exposes a part of the semiconductor layer.

57. A method for manufacturing the semiconductor device according to claim 43, the method comprising:
a step of forming the semi-insulating film so as to cover the moisture-resistant insulating film; and
an etching step of etching both the semi-insulating film and the moisture-resistant insulating film using a same etching mask to form an opening that penetrates both the semi-insulating film and the moisture-resistant insulating film and exposes a part of the outer peripheral electrode and the front surface electrode.

58. A method for manufacturing the semiconductor device according to claim 43, the method comprising:
a step of forming the semi-insulating film so as to cover the moisture-resistant insulating film; and
an etching step of etching both the semi-insulating film and the moisture-resistant insulating film using a same etching mask to form an opening that penetrates both the semi-insulating film and the moisture-resistant insulating film and exposes a part of the field insulating film and the front surface electrode.
